(19) United States
(12) Patent Application Publication
(10) Pub. No.: US 2021/0358884 A1
(43) Pub. Date: Nov. 18, 2021

(54) SEMICONDUCTOR DEVICE MANUFACTURING METHOD

(71) Applicant: DAICEL CORPORATION, Osaka-shi, Osaka (JP)

(72) Inventor: Naoko TSUJI, Tokyo (JP)

(73) Assignee: DAICEL CORPORATION, Osaka-shi, Osaka (JP)

(21) Appl. No.: 17/287,187

(22) PCT Filed: Oct. 18, 2019
(86) PCT No.: PCT/JP2019/041202

§ 371 Date: Apr. 21, 2021

(30) Foreign Application Priority Data
Oct. 23, 2018 (JP) 2018-199013

(51) Int. Cl. H01L 23/00; H01L 25/065; H01L 25/00; H01L 21/768

(52) U.S. Cl. CPC H01L 24/83; H01L 21/304; H01L 25/50; H01L 24/94; H01L 24/32; H01L 24/29; H01L 21/76898; H01L 2225/06541; H01L 2224/94; H01L 2224/32145; H01L 2224/2919; H01L 2224/83005; H01L 2224/83855; H01L 2924/0655; H01L 2924/0715; H01L 25/0657

(57) ABSTRACT

Provided is a semiconductor device manufacturing method through which semiconductor elements are multilayered through the lamination of wafers in which the semiconductor elements are fabricated, the method thereof being suited for efficiently manufacturing semiconductor devices while realizing a large number of wafer lamination. With the method of the present invention, at least two wafer laminates are formed, each wafer laminate having a laminated structure, the structure including a plurality of wafers including an element forming surface and a back surface, with the element forming surface and the back surface facing between adjacent wafers; a through electrode is formed in each wafer laminate with the through electrode extending through an inside of the wafer laminate, from an element forming surface side of a first wafer located at one end of the wafer laminate in a lamination direction, to a position exceeding an element forming surface of a second wafer located at another end; the through electrode is exposed at a back surface side of the second wafer by grinding the back surface side thereof; and two wafer laminates that have been subjected to this exposing step are laminated and bonded while electrically connecting the through electrodes between the wafer laminates.

### TECHNICAL FIELD

The present invention relates to a method of manufacturing a semiconductor device having a laminated structure including a plurality of semiconductor elements. The present application claims the rights of priority on the basis of JP 2018-199013 filed in Japan on Oct. 23, 2018, the contents of which are incorporated herein.

### BACKGROUND ART

In recent years, technology for manufacturing semiconductor devices having a three-dimensional structure in which a plurality of semiconductor chips or semiconductor elements are integrated in their thickness direction thereof has been developed primarily, for the purpose of further increasing the density of semiconductor devices. One of such a technology widely known is a wafer-on-wafer (WOW) process. In the WOW process, for example, a predetermined number of semiconductor wafers, each having a plurality semiconductor elements formed therein, are laminated in order, a structure is formed with the semiconductor elements arranged in multiple layers in the thickness direction thereof, and the wafer laminate is divided into individual semiconductor devices through dicing. Such a WOW process is described, for example, in Patent Documents 1 and 2 listed below.

### CITATION LIST

### Patent Document

Patent Document 1: WO 2010/032729

Patent Document 2: JP 2016-178162 A

### SUMMARY OF INVENTION

### Technical Problem

In the WOW process, so-called through electrodes are formed to electrically connect semiconductor elements between different semiconductor wafers. For example, in the wafer lamination process, each time a wafer of a next layer is laminated on a lower wafer, an electrode that passes through the laminated wafers in the thickness direction is formed, and an electrical connection of the semiconductor elements between both wafers is achieved. However, according to such a technique, a series of steps for forming a through electrode must be implemented for each laminated wafer, such as, for example, forming a through opening in the laminated wafers, forming an insulating film on an inner wall surface of the opening, filling the inside of the opening with a conductive material, and implementing a cleaning treatment of various aspects in association therewith, and thus such a technique is not efficient.

On the other hand, a technique is also known in which through electrodes for electrically connecting semiconductor elements between wafers are formed by implementing a series of steps that include: fabricating a wafer laminate with the number of lamination corresponding to the number of semiconductor element lamination in a design of a semiconductor device to be manufactured; and then forming, in the wafer laminate, openings extending across the plurality of wafers in the thickness direction thereof. However, as the number of wafer lamination in the wafer laminate increases, it tends to be difficult to appropriately form an opening extending across the plurality of wafers, and therefore, it tends to be difficult to appropriately form a through electrode in the opening.

The present invention was conceived in consideration of conditions like those described above, and an object of the present invention is to provide, in a semiconductor device manufacturing method through which semiconductor elements are multilayered through the lamination of wafers in which semiconductor elements are fabricated, a technique being suited for efficiently manufacturing semiconductor devices while realizing a large number of wafer lamination.

### Solution to Problem

A semiconductor device manufacturing method provided by the present invention includes a wafer laminate forming step, an electrode forming step, an electrode end part exposing step, and a multilayering step, as described below.

In the wafer laminate forming step, at least two wafer laminates are formed. Each wafer laminate has a laminated structure in which a plurality of wafers, each having an element forming surface and a back surface opposite to the element forming surface, are disposed such that the element forming surface of one of two adjacent wafers and the back surface of the other wafer face each other. With the wafer (first wafer) located at one end in the lamination direction of the wafer laminate, the adjacent wafer is positioned at the back surface side, and with the wafer (second wafer) located at the other end in the lamination direction of the wafer laminate, the adjacent wafer is positioned at the element forming surface side thereof. The element forming surface of the wafer is a side of the surface on which a plurality of semiconductor elements is formed through a transistor formation step, a wiring formation step, or the like. The number of wafer lamination may be the same or different between wafer laminates.

In the electrode forming step, at least one through electrode is formed in each wafer laminate. The through electrode extends through the inside of the wafer laminate, from the element forming surface of the above-described first wafer of the wafer laminate to a position exceeding the element forming surface of the above-described second wafer. This step preferably includes: a step of forming an opening extending from the element forming surface side of the first wafer to a position exceeding the element forming surface of the second wafer in the wafer laminate; and filling the inside of the opening with a conductive material.

In the electrode end part exposing step, the second wafer is thinned by grinding the back surface side of the second wafer of each wafer laminate that has been subjected to the electrode forming step, and the through electrode is exposed on the back surface side.

In the multilayering step, at least two wafer laminates that have undergone the electrode end part exposing step are laminated and bonded while electrically connecting the through electrodes between the wafer laminates. In this step, the element forming surface side of the first wafer of one wafer laminate to be bonded may be bonded to the element forming surface side of the first wafer of another wafer laminate (face-to-face bonding between wafer laminates). In this step, the element forming surface side of the first wafer of one wafer laminate to be bonded may be bonded to the back surface side of the second wafer of another wafer laminate (face-to-back bonding between wafer laminates). In this step, the back surface side of the second wafer of one wafer laminate to be bonded may be bonded to the back surface side of the second wafer of another wafer laminate (back-to-back bonding between wafer laminates).

In the electrode forming step described above with respect to the present semiconductor device manufacturing method, a through electrode is formed in each wafer laminate that is bonded to another wafer laminate in a subsequent multilayering step, the through electrode extending across a plurality of wafers contained in each wafer laminate. Such a configuration is suited for avoiding or reducing the implementation of a series of steps for forming through electrodes for each wafer in the process of forming a wafer laminate (that is, forming an opening through one wafer, forming an insulating film on an inner wall surface of the opening, filling the inside of the opening with a conductive material, implementing cleaning treatments of various aspects associated therewith, and the like) and is suitable for efficiently manufacturing a semiconductor device in a WOW process.

In the above-described multilayering step of the present semiconductor device manufacturing method, at least two wafer laminates in which through electrodes are already formed are bonded while the through electrodes are electrically connected between the wafer laminates thereof, and wafers are further multilayered. Such a configuration is suitable for achieving a large number of wafer lamination in the WOW process.

As described above, as the number of wafer lamination in the wafer laminate increases, it tends to be difficult to appropriately form an opening extending across the plurality of wafers in a laminate thickness direction, and it tends to be difficult to appropriately form a through electrode in the opening. However, with the present semiconductor device manufacturing method, there is no need to form electrodes that collectively penetrate a wafer laminate having the number of lamination corresponding to the number of semiconductor element lamination of the semiconductor device to be manufactured. This type of semiconductor device manufacturing method is suitable for avoiding or suppressing the aforementioned difficulties associated with the batch formation of through electrodes.

As described above, the present semiconductor device manufacturing method is suitable for efficiently manufacturing semiconductor devices while avoiding or suppressing difficulties in the formation of through electrodes associated with an increase in wafer laminates and achieving a large number of wafer lamination.

In addition, the present semiconductor device manufacturing method is suitable for increasing the density of semiconductor elements in each wafer when a technique described in, for example, JP 2016-004835 A is employed as the through electrode forming technique in the electrode forming step described above. According to the through electrode forming technique described in the above document, a partially conductive portion is formed within each wafer, and these partial conductive portions are connected to each other to form a through electrode. However, these partially conductive portions have different cross-sectional areas (cross-sectional areas in the wafer in-plane direction) between adjacent wafers, resulting in a structure in which the cross-sectional area of the partially conductive portion inevitably gradually increases from wafer to wafer as the number of wafer lamination increases. Such a structure will have a difficulty in increasing the density of semiconductor elements in each wafer as the number of wafer lamination increases. However, with the present semiconductor device manufacturing method, there is no need to form electrodes that collectively penetrate a wafer laminate having the number of lamination corresponding to the number of semiconductor element lamination of the semiconductor device to be manufactured. Such a present semiconductor device manufacturing method is suitable for increasing the density of semiconductor elements in each wafer while increasing the number of wafer lamination.

In a preferred first aspect, the wafer laminate forming step further includes: a step of bonding a wafer to an element forming surface side of a base wafer including the element forming surface and a back surface opposite therefrom; a step of forming a thinned wafer on the base wafer by grinding the wafer; and a step of forming a semiconductor element on a ground surface side of the thinned wafer. This type of wafer laminate forming step may further include a step of bonding a wafer to an element forming surface side of the thinned wafer on the base wafer; a step of forming a thinned wafer on the base wafer by grinding the wafer; and a step of forming a semiconductor element on a ground surface side of the thinned wafer. These configurations are suitable for forming a laminate of thin wafers in which semiconductor elements are fabricated.

In a preferred second aspect, the wafer laminate forming step includes a preparation step, a thinning step, a bonding step, and a removing step.

In the preparation step, a reinforced wafer is prepared. The reinforced wafer has a laminated structure including a wafer including an element forming surface and a back surface opposite from the element forming surface, a supporting substrate, and a temporary adhesive layer located between the element forming surface side of the wafer and the supporting substrate. The temporary adhesive layer is used to achieve temporary adhesion between the wafer and the supporting substrate.

In the thinning step, the wafer in such a reinforced wafer is ground from the back surface side of the wafer and thinned. This forms a thinned wafer in a state of being supported by the supporting substrate.

In the bonding step, an element forming surface side of a base wafer including the element forming surface and a back surface opposite from the element forming surface is bonded via an adhesive to the back surface side of the thinned wafer described above of the reinforced wafer. This bonding step preferably includes curing treatment to cure the adhesive at a temperature lower than a softening point of the polymer in the temporary adhesive layer. In such a bonding step, for example, the adhesive is coated on one or both surfaces to be bonded (the element forming surface of the base wafer, the back surface of the thinned wafer), the surfaces to be bonded are affixed via the adhesive, and the adhesive is cured after the affixing. In addition, in the bonding step, prior to the coating of the adhesive, one or both of the surfaces to be bonded may be treated with a silane coupling agent.

In the removing step, the temporary adhesion by the temporary adhesive layer between the supporting substrate and the thinned wafer in the reinforced wafer having undergone the bonding step described above is released to remove the supporting substrate. This removing step preferably includes softening treatment to soften the temporary adhesive layer at a temperature higher than the softening point of the polymer in the temporary adhesive layer.

The wafer laminate forming step including the preparation step, thinning step, bonding step, and removing step as described above is suitable for forming a laminate of thin wafers in which semiconductor elements are fabricated.

In a preferred second aspect, the wafer laminate forming step may further include: a step of preparing at least one additional reinforced wafer; a thinning step for each additional reinforced wafer; an additional bonding step for each additional reinforced wafer; and a removing step after the additional bonding step. The additional reinforced wafer has a laminated structure including a wafer including an element forming surface and a back surface opposite from the element forming surface, a supporting substrate, and a temporary adhesive layer between the element forming surface side of the wafer and the supporting substrate. In the thinning step for each additional reinforced wafer, the wafer in such an additional reinforced wafer is ground from the back surface side of the wafer to form a thinned wafer. In the additional bonding step for each additional reinforced wafer, the back surface side of the thinned wafer in the additional reinforced wafer is bonded to the element forming surface side of the thinned wafer on the base wafer through an adhesive. The thinned wafer on the base wafer is a thinned wafer bonded to the base wafer in the bonding step described above or a thinned wafer additionally laminated on the thinned wafer in a preceding additional bonding step. This step preferably includes curing treatment to cure the adhesive at a temperature lower than a softening point of the polymer in the temporary adhesive layer. In such an additional bonding step, for example, the adhesive is coated on one or both surfaces to be bonded (the element forming surface of one thinned wafer, the back surface of the other thinned wafer), the surfaces to be bonded are affixed via the adhesive, and the adhesive is cured after the affixing. In addition, in the additional bonding step, prior to the coating of the adhesive, one or both of the surfaces to be bonded may be treated with a silane coupling agent. Then, in the removing step after the additional bonding step, the temporary adhesion by the temporary adhesive layer between the supporting substrate and the thinned wafer in the additional reinforced wafer is released to remove the supporting substrate. This step preferably includes softening treatment to soften the temporary adhesive layer at a temperature higher than the softening point of the polymer in the temporary adhesive layer. Such a configuration is suitable for further multilayering a thin wafer in which semiconductor elements are fabricated.

The temporary adhesive for forming the above-described temporary adhesive layer in the reinforced wafer preferably contains a polyvalent vinyl ether compound; a compound having two or more hydroxy groups or carboxy groups that are capable of forming an acetal bond by reacting with a vinyl ether group of the polyvalent vinyl ether compound, the compound capable of forming a polymer with the polyvalent vinyl ether compound; and a thermoplastic resin. In the form of the temporary adhesive layer formed by solidification of the temporary adhesive between the supporting substrate and the wafer, the temporary adhesive thus configured is suitable for achieving a relatively high softening temperature of 120° C. or more, for example, 130 to 250° C. while ensuring high adhesive strength that can withstand the grinding or the like of the wafer in the thinning step.

The above-described adhesive used in the bonding step preferably contains a polyorganosilsesquioxane having a polymerizable functional group (i.e., a polymerizable group-containing polyorganosilsesquioxane). The polymerizable group-containing polyorganosilsesquioxane is suitable for achieving a relatively low polymerization temperature or curing temperature of, for example, approximately 30 to 200° C. and is suitable for achieving high heat resistance after curing. Thus, the wafer-to-wafer adhesive bonding with the adhesive containing the polymerizable group-containing polyorganosilsesquioxane is suitable for achieving high heat resistance in an adhesive layer to be formed between the wafers as well as achieving lower curing temperature for forming the adhesive layer and thus preventing damages to the elements in the wafer as an adherend.

In the second preferred aspect of the wafer laminate forming step in the present semiconductor device manufacturing method, when the above-described preferred configuration is adopted for both the temporary adhesive for forming the temporary adhesive layer and the adhesive for bonding between wafers, a composite and functional configuration like that described below can be realized. As described above, the temporary adhesive layer in the reinforced wafer to be subjected to the bonding step is suitable for achieving a relatively high softening temperature, and as also described above, the adhesive (adhesive containing a polymerizable group-containing polyorganosilsesquioxane) used in the bonding step is suitable for achieving a relatively low curing temperature and high heat resistance after curing. Such a composite and functional configuration is suitable for implementing both the bonding step and the subsequent removing step. That is, the configuration thereof is suitable for implementing the bonding step at a relatively low temperature condition to achieve good adhesive bonding of the thinned wafer to the base wafer while maintaining the temporary adhesion between the thinned wafer and the supporting substrate in the reinforced wafer, and the configuration thereof is also suitable for implementing the subsequent removing step at a relatively high temperature condition to soften the temporary adhesive layer and to remove the supporting substrate from the thinned wafer while maintaining the adhesive bonding between the base wafer and the thinned wafer. The configuration of releasing the temporary adhesion by the temporary adhesive layer through softening the temporary adhesive layer in removing the supporting substrate from the thinned wafer is suitable for avoiding or preventing a strong stress applied locally to the thinned wafer to avoid damage to the wafer. The abovementioned composite configuration of the second preferred aspect of the wafer laminate forming step is suitable for multilayering thin wafers through adhesive bonding while avoiding wafer damage when forming the wafer laminate.

### BRIEF DESCRIPTION OF DRAWINGS

FIG. 1 illustrates some of the steps in a semiconductor device manufacturing method according to one embodiment of the present invention.

FIG. 2 illustrates some of the steps in a semiconductor device manufacturing method according to one embodiment of the present invention.

FIG. 3 illustrates some of the steps in a semiconductor device manufacturing method according to one embodiment of the present invention.

FIG. 4 illustrates some of the steps in a semiconductor device manufacturing method according to one embodiment of the present invention.

FIG. 5 illustrates some of the steps in a semiconductor device manufacturing method according to one embodiment of the present invention.

FIG. 6 illustrates some of the steps in a semiconductor device manufacturing method according to one embodiment of the present invention.

FIG. 7 illustrates some of the steps in a semiconductor device manufacturing method according to one embodiment of the present invention.

FIG. 8 illustrates some of the steps in a semiconductor device manufacturing method according to one embodiment of the present invention.

FIG. 9 illustrates some of the steps in a semiconductor device manufacturing method according to one embodiment of the present invention.

FIG. 10 illustrates some of the steps in a semiconductor device manufacturing method according to one embodiment of the present invention.

FIG. 11 illustrates some of the steps in a semiconductor device manufacturing method according to one embodiment of the present invention.

FIG. 12 illustrates some of the steps in a semiconductor device manufacturing method according to one embodiment of the present invention.

FIG. 13 illustrates an example of a through electrode forming step.

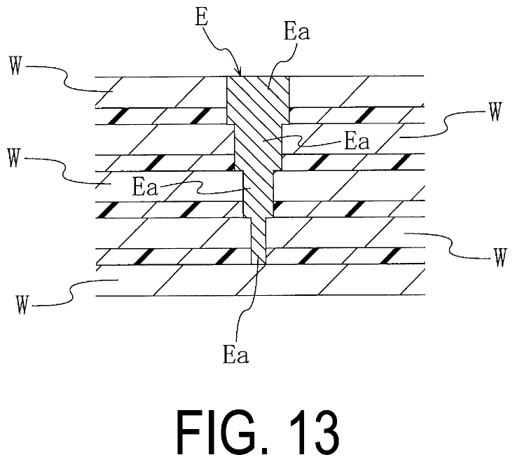

FIG. 14 illustrates an example of a wafer laminate forming step.

FIG. 15 illustrates a subsequent step of FIG. 14.

### DESCRIPTION OF EMBODIMENTS

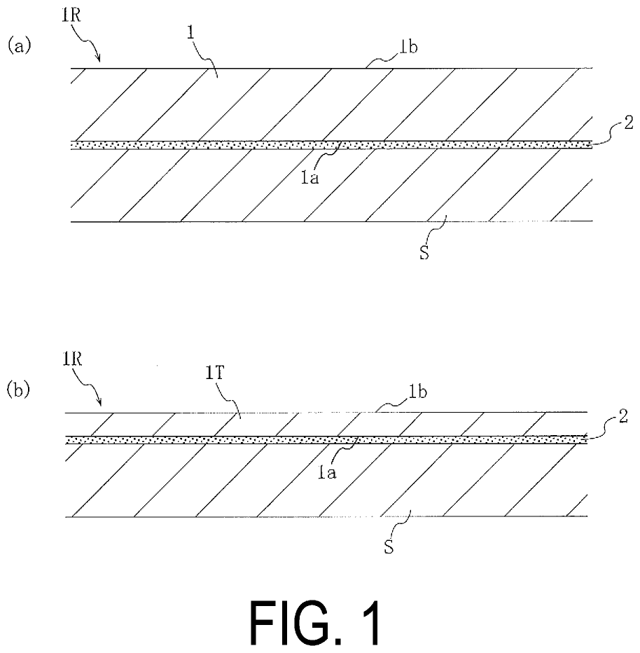

FIG. 1 to FIG. 12 illustrate a semiconductor device manufacturing method according to an embodiment of the present invention. This manufacturing method is a method of manufacturing a semiconductor device having a three-dimensional structure in which semiconductor elements are integrated in the thickness direction thereof, and FIG. 1 to FIG. 12 illustrate the manufacturing processes in partial cross-sectional views.

In the present semiconductor device manufacturing method, first, a reinforced wafer 1R as illustrated in FIG. 1(a) is prepared (preparation step). The reinforced wafer 1R has a laminated structure including a wafer 1, a supporting substrate S, and a temporary adhesive layer 2 between the wafer 1 and the supporting substrate S.

The wafer 1 is a wafer including a semiconductor wafer main body in which a semiconductor element can be fabricated and includes an element forming surface 1a and a back surface 1b opposite from the element forming surface 1a. In the present embodiment, the element forming surface of the wafer is a surface on the side on which a plurality of semiconductor elements (not illustrated) are formed in the wafer through a transistor formation step, a wiring formation step, and the like. Each semiconductor element of the wafer 1 includes, for example, a multi-layered wiring structure portion including an exposed electrode pad on a surface. Alternatively, the wafer 1 may be a wafer in which various semiconductor elements are already fabricated on the side of the element forming surface 1a, and a wiring structure necessary for the semiconductor elements is subsequently formed on the element forming surface 1a. Examples of a constituent material for forming the semiconductor wafer main body of the wafer 1 include silicon (Si), germanium (Ge), silicon carbide (SiC), gallium arsenide (GaAs), gallium nitride (GaN), and indium phosphide (InP). The thickness of such a wafer 1 is preferably not greater than 1000 μm, more preferably not greater than 900 μm, and more preferably not greater than 800 μm from the perspective of reducing the grinding time in grinding described later. In addition, the thickness of the wafer 1 is, for example, not less than 500 μm.

The supporting substrate S in the reinforced wafer 1R is for reinforcing the wafer 1 to be thinned through a thinning step described below. Examples of the supporting substrate S include silicon wafers and glass wafers. From the perspective of ensuring a function as a reinforcing element, the thickness of the supporting substrate S is preferably not less than 300 μm, more preferably not less than 500 μm, and more preferably not less than 700 μm. In addition, the thickness of the supporting substrate S is, for example, not greater than 800 μm. Such a supporting substrate S is bonded to the side of the element forming surface 1a of the wafer 1 via the temporary adhesive layer 2.

The temporary adhesive layer 2 is for achieving temporary adhesion between the wafer 1 and the supporting substrate S, and the temporary adhesion that can be subsequently released. In the present embodiment, the temporary adhesive for forming such a temporary adhesive layer 2 contains at least: a polyvalent vinyl ether compound (A); a compound (B) having two or more hydroxy groups or carboxy groups that are capable of forming an acetal bond by reacting with a vinyl ether group of the polyvalent vinyl ether compound (A), the compound (B) capable of forming a polymer with the polyvalent vinyl ether compound (A); and a thermoplastic resin (C).

Each of these components in the temporary adhesive is as specifically described below. As temporary adhesive for forming the temporary adhesive layer 2, a silicone-based tacky adhesive, an acrylic-based tacky adhesive, or a wax-type adhesive may be used instead of such temporary adhesive.

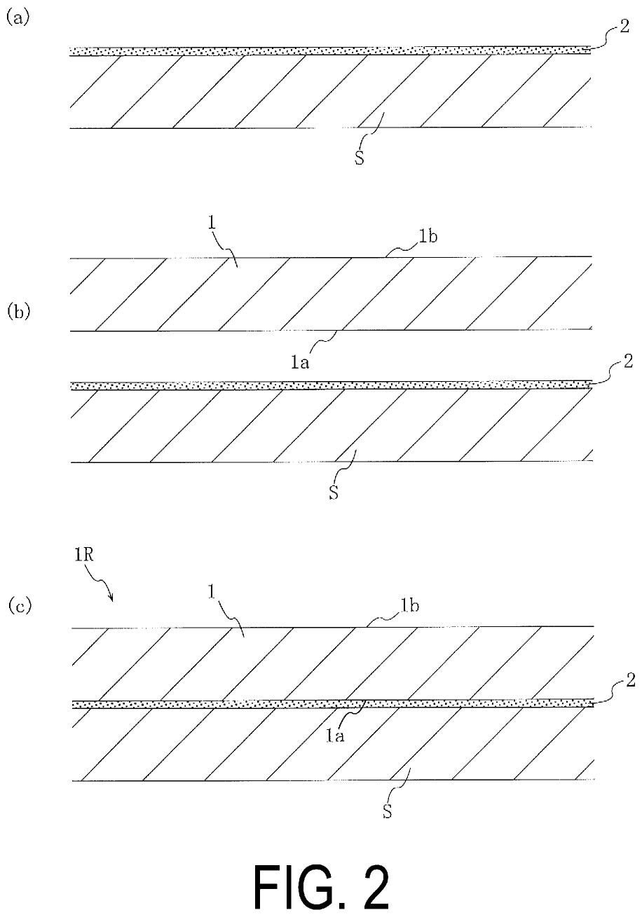

The reinforced wafer 1R thus configured as such can be produced, for example, through steps as follows. First, as illustrated in FIG. 2(a), the temporary adhesive layer 2 is formed on the supporting substrate S. Specifically, temporary adhesive for forming the temporary adhesive layer 2 is coated on the supporting substrate S, for example, by spin coating to form a temporary adhesive coating. The coating is dried by heating, and the temporary adhesive layer 2 can be formed. The temperature of the heating is, for example, from 100 to 300° C., and may be constant or may be changed stepwise. The heating time is, for example, from 30 seconds to 30 minutes. Next, as illustrated in FIGS. 2(b) and 2(c), the supporting substrate S and the wafer 1 are bonded via the temporary adhesive layer 2. As described above, the wafer 1 includes the element forming surface 1a and the back surface 1b opposite from the element forming surface 1a. In the present step, for example, the supporting substrate S and the wafer 1 are affixed via the temporary adhesive layer 2 under pressure, then the temporary adhesive layer 2 is solidified through heating to form a polymer having a softening point in a high-temperature range, and the supporting substrate S and the wafer 1 are adhered with the temporary adhesive layer 2. In the affixing, the pressure is, for example, from 300 to 5000 g/cm², and the temperature is, for example, from 30 to 200° C. In addition, in the adhesion with the temporary adhesive layer 2, the heating temperature is, for example, from 100 to 300° C. and preferably from 100 to 250° C., and the heating time is, for example, from 30 seconds to 30 minutes and preferably from 3 to 12 minutes. The heating temperature may be constant or may be changed stepwise. As described above, the reinforced wafer 1R having a laminated structure including the wafer 1, the supporting substrate S, and the temporary adhesive layer 2 between the wafer 1 and the supporting substrate S can be fabricated.

The polyvalent vinyl ether compound (A) described above in the temporary adhesive is a compound having two or more vinyl ether groups in a molecule and is represented, for example, by Formula (a) below.

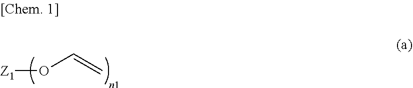

In Formula (a), Z₁ represents a group in which a quantity of n₁ hydrogen atoms are removed from a structural formula of a saturated or unsaturated aliphatic hydrocarbon, a saturated or unsaturated alicyclic hydrocarbon, an aromatic hydrocarbon, a heterocyclic compound, or a bonded body in which any of these are bonded via a single bond or a linking group. In addition, in Formula (a), n₁ represents an integer of 2 or greater, for example, an integer of 2 to 5, and preferably an integer of 2 or 3.

Among the groups in which n₁ hydrogen atoms are removed from a structural formula of a saturated or unsaturated aliphatic hydrocarbon, examples of the group in which two hydrogen atoms are removed from a structural formula of a saturated or unsaturated aliphatic hydrocarbon may include linear or branched alkylene groups, such as a methylene group, an ethylene group, a propylene group, a trimethylene group, a tetramethylene group, a pentamethylene group, a hexamethylene group, an octamethylene group, a decamethylene group, and a dodecamethylene group; and linear or branched alkenylene groups, such as a vinylene group, a 1-propenylene group, and 3-methyl-2-butenylene group. The alkylene group has, for example, from 1 to 20 carbon atoms and preferably has from 1 to 10 carbon atoms. The alkenylene group has, for example, from 2 to 20 carbon atoms and preferably has from 2 to 10 carbon atoms. Examples of the group in which three or more hydrogen atoms are removed from a structural formula of a saturated or unsaturated aliphatic hydrocarbon may include groups in which one or more hydrogen atoms are further removed from the structural formula of any of these groups exemplified.

Among the groups in which n₁ hydrogen atoms are removed from a structural formula of a saturated or unsaturated alicyclic hydrocarbon, examples of the group in which two hydrogen atoms are removed from a structural formula of a saturated or unsaturated alicyclic hydrocarbon may include: cycloalkylene groups of a 3- to 15-membered ring, such as a 1,2-cyclopentylene group, a 1,3-cyclopentylene group, a 1,2-cyclohexylene group, a 1,3-cyclohexylene group, and a 1,4-cyclohexylene group; cycloalkenylene groups of a 3- to 15-membered ring, such as a cyclopentenylene group and a cyclohexenylene group; cycloalkylidene groups of a 3- to 15-membered ring, such as a cyclopentylidene group and a cyclohexylidene group; and divalent bridged cyclic hydrocarbon groups of a 4- to 15-membered ring, such as an adamantanediyl group, a norbornanediyl group, a norbornenediyl group, an isobornanediyl group, a tricyclodecanediyl group, a tricycloundecanediyl group, and a tetracyclododecanediyl group. Examples of the group in which three or more hydrogen atoms are removed from a structural formula of a saturated or unsaturated alicyclic hydrocarbon may include groups in which one or more hydrogen atoms are further removed from the structural formula of any of these groups exemplified.

Examples of the aromatic hydrocarbon may include benzene, naphthalene, and anthracene.

The heterocyclic compound includes aromatic heterocyclic compounds and non-aromatic heterocyclic compounds. Examples of such heterocyclic compounds may include: heterocyclic compounds containing an oxygen atom as a heteroatom (e.g., 5-membered rings, such as furan, tetrahydrofuran, oxazole, isooxazole, and γ-butyrolactone; 6-membered rings, such as 4-oxo-4H-pyran, tetrahydropyran, and morpholine; fused rings, such as benzofuran, isobenzofuran, 4-oxo-4H-chromene, chroman, and isochroman; and bridged rings, such as 3-oxatricyclo[4.3.1.1^{4,8}]undecan-2-one and 3-oxatricyclo[4.2.1.0^{4,8}]nonan-2-one), heterocyclic compounds containing a sulfur atom as a heteroatom (e.g., 5-membered rings, such as thiophene, thiazole, isothiazole, and thiadiazole; 6-membered rings, such as 4-oxo-4H-thiopyran; and fused rings, such as benzothiophene), and heterocyclic compounds containing a nitrogen atom as a heteroatom (e.g., 5-membered rings, such as pyrrole, pyrrolidine, pyrazole, imidazole, and triazole; 6-membered rings, such as pyridine, pyridazine, pyrimidine, pyrazine, piperidine, and piperazine; and fused rings, such as indole, indoline, quinoline, acridine, naphthyridine, quinazoline, and purine).

Examples of the linking group may include divalent to tetravalent hydrocarbon groups, a carbonyl group (—CO—), an ether bond (—O—), a sulfide bond (—S—), an ester bond (—COO—), an amide bond (—CONH—), a carbonate bond (—OCOO—), a urethane bond (—NHCOO—), an —NR— bond (R represents a hydrogen atom, an alkyl group, or an acyl group), and groups in which a plurality of these groups are linked. Among the divalent to tetravalent hydrocarbon groups, examples of the divalent hydrocarbon group may include: linear or branched alkylene groups having from 1 to 10 carbon atoms, such as a methylene group, a methylmethylene group, a dimethylmethylene group, an ethylene group, a propylene group, and a trimethylene group; and alicyclic hydrocarbon groups having from 4 to 15 carbon atoms (in particular, cycloalkylene groups), such as a 1,2-cyclopentylene group, a 1,3-cyclopentylene group, a cyclopentylidene group, a 1,2-cyclohexylene group, a 1,3-cyclohexylene group, a 1,4-cyclohexylene group, and a cyclohexylidene group. Examples of the trivalent hydrocarbon group may include a group in which one hydrogen atom is removed from a structural formula of the divalent hydrocarbon group. Examples of the tetravalent hydrocarbon group may include a group in which two hydrogen atoms are removed from a structural formula of the divalent hydrocarbon group.

Z₁ may have one or two or more types of substituents. Examples of the substituent may include alkyl groups, cycloalkyl groups, alkenyl groups, cycloalkenyl groups, aryl groups, hydroxy groups, carboxy groups, nitro groups, amino groups, mercapto groups, halogen atoms, C₂₋₁₀ hydrocarbon groups substituted with a halogen atom, hydrocarbon groups containing a functional group containing a heteroatom (such as oxygen or sulfur), and a group in which two or more of these groups are bonded. Examples of the alkyl groups include C₁₋₄ alkyl groups, such as a methyl group and an ethyl group. Examples of the cycloalkyl groups include C₃₋₁₀ cycloalkyl groups. Examples of the alkenyl groups include C₂₋₁₀ alkenyl groups, such as a vinyl group. Examples of the cycloalkenyl groups include C₃₋₁₀ cycloalkenyl groups. Examples of the aryl groups include C₆₋₁₅ aryl groups, such as a phenyl group and a naphthyl group. Examples of the hydrocarbon groups containing a heteroatom-containing functional group include C₁₋₄ alkoxy groups and C₂₋₆ acyloxy groups.

Specific examples of the polyvalent vinyl ether compound (A) may include 1,4-butanediol divinyl ether, diethylene glycol divinyl ether, and triethylene glycol divinyl ether, and compounds represented by Formulas (a-1) to (a-21) below.

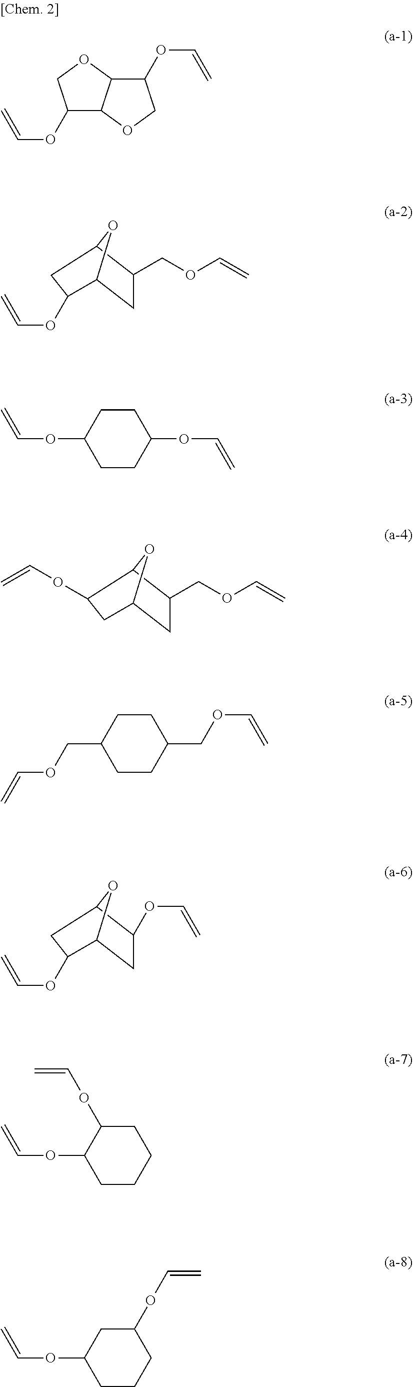

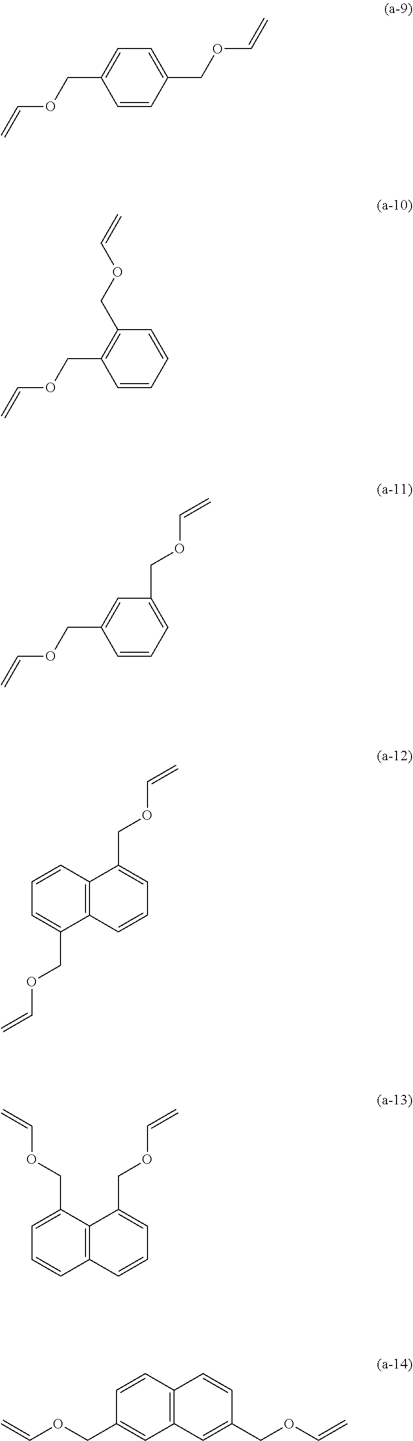

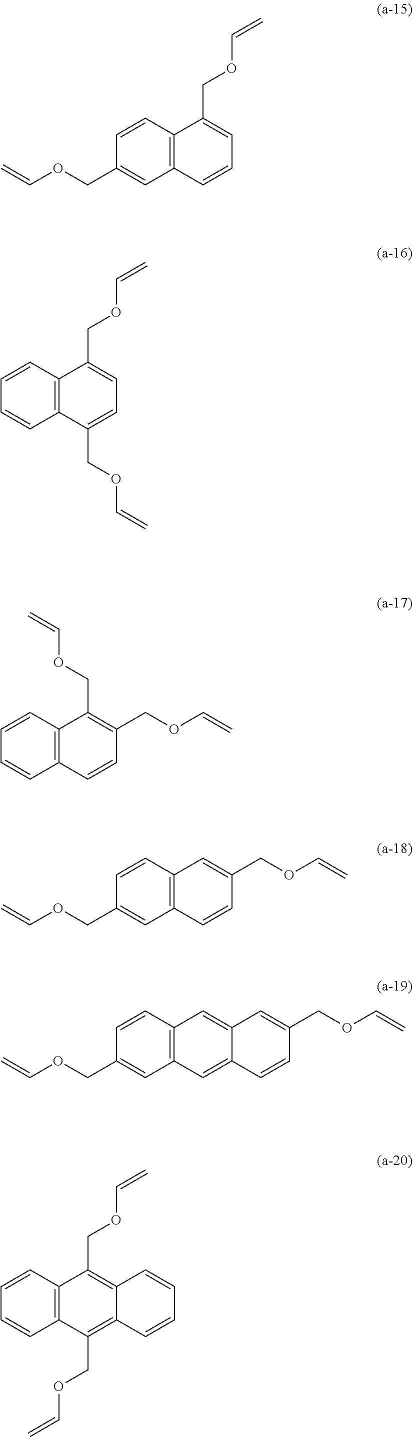

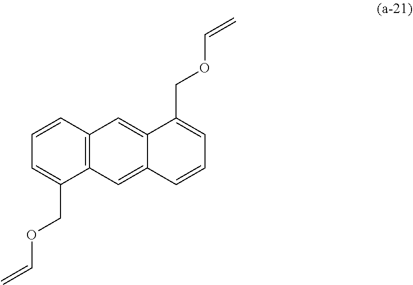 [SMILES: C=COCc1cccc2cc3c(COC=C)cccc3cc12]

From the perspective of forming a polymer having a high softening point in the temporary adhesive described above, Z₁ above in the polyvalent vinyl ether compound (A) is: preferably a group in which n₁ hydrogen atoms are removed from a structural formula of a saturated or unsaturated aliphatic hydrocarbon, or a bonded body in which a plurality of the hydrocarbons are bonded via a linking group; more preferably a group in which n₁ hydrogen atoms are removed from a structural formula of a saturated aliphatic hydrocarbon or a bonded body in which a plurality of the hydrocarbons are bonded via a linking group; and more preferably a group in which n₁ hydrogen atoms are removed from a structural formula of a linear alkylene group having from 1 to 20 carbon atoms, a branched alkylene group having from 2 to 20 carbon atoms, or a bonded body in which a plurality of the alkylene groups are bonded via a linking group.

The polyvalent vinyl ether compound (A) is most preferably at least one compound selected from the group consisting of 1,4-butanediol divinyl ether, diethylene glycol divinyl ether, and triethylene glycol divinyl ether.

As described above, the compound (B) in the temporary adhesive is a compound having two or more hydroxy groups or carboxy groups that are capable of forming an acetal bond by reacting with a vinyl ether group of the polyvalent vinyl ether compound (A), the compound (B) capable of forming a polymer with the polyvalent vinyl ether compound (A), and, for example, is a compound having two or more constituent units (repeating units) represented by Formula (b) below.

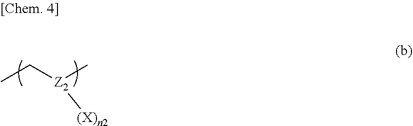

In Formula (b), X represents a hydroxy group or a carboxy group. n₂ X's may be identical or different from each other.

In Formula (b), n₂ represents an integer of 1 or greater. From the perspective of ease of obtaining and ease of dissolving in a solvent in preparing the temporary adhesive described above, and from the perspective of forming a polymer having a high softening point in the temporary adhesive, n₂ is preferably an integer of 1 to 3 and more preferably an integer of 1 or 2.

The number of constituent units (repeating units) represented by Formula (b) above in the compound (B) is 2 or greater, and from the perspective of forming a polymer having a high softening point in the temporary adhesive described above, the number is preferably an integer of 2 to 40 and more preferably an integer of 10 to 30.

In Formula (b), Z₂ represents a group in which (n₂+2) hydrogen atoms are removed from a structural formula of a saturated or unsaturated aliphatic hydrocarbon, a saturated or unsaturated alicyclic hydrocarbon, an aromatic hydrocarbon, a heterocyclic compound, or a bonded body in which any of these are bonded via a single bond or a linking group. Examples of the structural formula of a saturated or unsaturated aliphatic hydrocarbon, a saturated or unsaturated alicyclic hydrocarbon, an aromatic hydrocarbon, a heterocyclic compound, or a bonded body in which any of these are bonded via a single bond or a linking group may include examples similar to the examples in Z₁ described above.

The compound (B) is preferably a styrene polymer, a (meth)acrylic polymer, a polyvinyl alcohol, a novolac resin, and a resole resin, and more preferably a compound having two or more of at least one type of constituent unit (repeating unit) selected from the group consisting of Formulas (b-1) to (b-6) below.

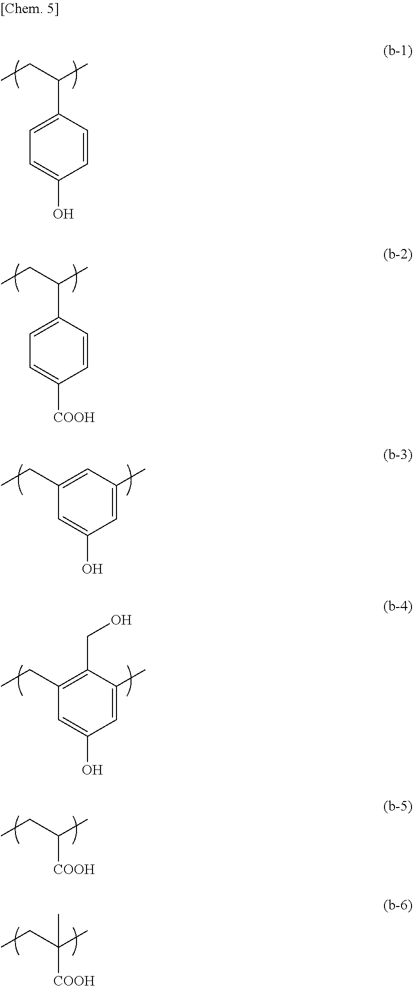

When a compound in which X in Formula (b) is a hydroxy group is employed as the compound (B), the proportion of the constituent units represented by Formula (b) in the total amount of the compound (B) is preferably not less than 30 mass %, more preferably not less than 50 mass %, and more preferably not less than 60 mass %. In addition, the proportion of the constituent units represented by Formula (b) in the total amount of the compound (B) is preferably not less than 30 mol % and more preferably not less than 50 mol %.

When a compound in which X in Formula (b) is a carboxy group is employed as the compound (B), the proportion of the constituent units represented by Formula (b) in the total amount of the compound (B) is preferably not less than 1 mass %, more preferably not less than 5 mass %, and more preferably not less than 10 mass %.

When the proportion of the constituent units represented by Formula (b) is within the above range, such proportion is suitable for ensuring a sufficient distance between crosslinking points and a sufficient number of crosslinking points in the compound (B). Thus, the abovementioned proportion is suitable for ensuring the weight average molecular weight and a high softening point of the polymer obtained through polymerization of the compound (B) and the above-described polyvalent vinyl ether compound (A) in the temporary adhesive described above. In addition, the proportion thereof is suitable for ensuring high adhesion retentivity in the temporary adhesive layer 2 formed from the temporary adhesive in high temperature environments.

The compound (B) may be a homopolymer having only the constituent units represented by Formula (b) or may be a copolymer having the constituent units represented by Formula (b) and any other constituent unit. When the compound (B) is a copolymer, the compound (B) may be any of a block copolymer, a graft copolymer, and a random copolymer.

The any other constituent unit in the compound (B) is a constituent unit derived from a polymerizable monomer, the constituent unit having neither a hydroxy group nor a carboxy group, and examples of the polymerizable monomer include olefins, aromatic vinyl compounds, unsaturated carboxylic acid esters, carboxylic acid vinyl esters, and unsaturated dicarboxylic acid diesters. Examples of the olefins include chain olefins (in particular, C₂₋₁₂ alkenes), such as ethylene, propylene, and 1-butene; and cyclic olefins (in particular, C₃₋₁₀ cycloalkenes), such as cyclopentene, cyclohexene, cycloheptene, norbornene, 5-methyl-2-norbornene, and tetracyclododecene. Examples of the aromatic vinyl compounds include C₆₋₁₄ aromatic vinyl compounds, such as styrene, vinyl toluene, α-methylstyrene, 1-propenylbenzene, 1-vinylnaphthalene, 2-vinylnaphthalene, 3-vinylpyridine, 3-vinylfuran, 3-vinylthiophene, 3-vinylquinoline, indene, methylindene, ethylindene, and dimethylindene. Examples of the unsaturated carboxylic acid esters include: esters, such as ethyl (meth)acrylate, butyl (meth)acrylate, isobutyl (meth)acrylate, 2-ethylhexyl (meth)acrylate, and dicyclopentanyl (meth)acrylate, obtained by reacting an unsaturated carboxylic acid (e.g., (meth)acrylic acid) with an alcohol (R″—OH). (The R″ is a group in which one hydrogen atom is removed from a structural formula of a saturated or unsaturated aliphatic hydrocarbon, a saturated or unsaturated alicyclic hydrocarbon, an aromatic hydrocarbon, a heterocyclic compound, or a bonded body in which any of these are bonded through a single bond or a linking group. Examples of R″ may include monovalent groups corresponding to the divalent groups listed for Z₁ in Formula (a) above.) Examples of the carboxylic acid vinyl esters include C₁₋₁₆ fatty acid vinyl esters, such as vinyl acetate, vinyl propionate, vinyl caprylate, and vinyl caproate. Examples of the unsaturated dicarboxylic acid diesters may include maleic acid di C₁₋₁₀ alkyl esters, such as diethyl maleate, dibutyl maleate, dioctyl maleate, and 2-ethylhexyl maleate; and fumaric acid diesters corresponding to these esters. One of these polymerization accelerators can be used alone or two or more in combination.

When the compound (B) is a copolymer, the compound (B) is preferably a compound containing: the constituent units represented by Formula (b) above; and a constituent unit derived from at least one polymerizable monomer selected from the group consisting of a chain olefin, a cyclic olefin, an aromatic vinyl compound, an unsaturated carboxylic acid ester, a carboxylic acid vinyl ester, and an unsaturated dicarboxylic acid diester.

A softening point (Ti) of the compound (B) is, for example, not lower than 50° C., preferably not lower than 80° C., and more preferably not lower than 100° C. Such a configuration is suitable for achieving a high softening point for a polymer obtained by polymerization of the compound (B) and the polyvalent vinyl ether compound (A) described above. In addition, from the perspective of ensuring proper fluidity to achieve good coating properties in the temporary adhesive described above, T₁ is, for example, not higher than 250° C., preferably not higher than 200° C., and more preferably not higher than 150° C.

T₁ can be adjusted for example, by controlling the weight average molecular weight (by the GPC method calibrated with polystyrene standards) of the compound (B). The weight average molecular weight of the compound (B) is, for example, not lower than 1500, preferably from 1800 to 10000, and more preferably from 2000 to 5000.

The thermoplastic resin (C) described above in the temporary adhesive needs to be a compound having thermoplasticity and capable of imparting flexibility to an adhesive composition when contained in the adhesive composition. Examples of such a thermoplastic resin (C) may include polycondensation resins, such as polyvinyl acetal resins, polyester resins, polyurethane resins, polyamide resins, poly(thio)ether resins, polycarbonate resins, polysulfone resins, and polyimide resins; vinyl polymerized resins, such as polyolefin resins, (meth)acrylic resins, styrene resins, and vinyl resins; and resins derived from natural products, such as cellulose derivatives. One of these polymerization accelerators can be used alone or two or more in combination. The configuration in which the temporary adhesive described above contains such a thermoplastic resin (C) is suitable for imparting flexibility or pliability in the temporary adhesive layer 2 to be formed, is suitable for preventing the occurrence of spontaneous peeling or cracking also in an environment where the temperature changes rapidly, and is suitable for ensuring excellent adhesiveness.

The thermoplastic resin (C) in the temporary adhesive is preferably at least one selected from the group consisting of polyvinyl acetal resins, polyester resins, polyurethane resins, and polyamide resins. From the perspective of easily imparting flexibility in the temporary adhesive or the temporary adhesive layer 2, and from the perspective of easily removing a glue residue if chemical interaction to an adherend, such as a wafer, reduces, and a glue residue remains on the adherend after peeling, the temporary adhesive preferably contains a polyester resin as the thermoplastic resin (C). Furthermore, in addition to the perspective of easily imparting flexibility in the temporary adhesive or the temporary adhesive layer 2 and the perspective of easily removing a glue residue on an adherend, from the perspective of ensuring high adhesion to an adherend, the temporary adhesive preferably contains a polyester resin and a polyvinyl acetal resin as the thermoplastic resins (C).

Examples of the polyvinyl acetal resin may include resins having at least a constituent unit represented by the formula below, the constituent unit obtained by reacting an aldehyde (RCHO) with a polyvinyl alcohol. Examples of the aldehyde (RCHO) include compounds in which R in the structural formula (R in the formula below is also the same) is a hydrogen atom, a linear C₁₋₅ alkyl group, a branched C₂₋₅ alkyl group, or a C₆₋₁₀ aryl group. Examples specifically include formaldehyde, butyraldehyde, and benzaldehyde. Such a polyvinyl acetal resin may have any other constituent unit in addition to the constituent unit represented by the formula below. That is, the polyvinyl acetal resin includes a homopolymer and a copolymer.

Examples of such a polyvinyl acetal resin may specifically include polyvinyl formal and polyvinyl butyral, and a commercially available product, for example, “S-LEC KS-1 (trade name)” or “S-LEC KS-10 (trade name)” (both available from Sekisui Chemical Co., Ltd.) can be used.

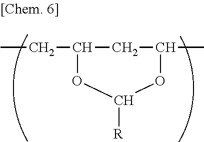

Examples of the polyester resin include polyesters obtained by polycondensation of a diol component and a dicarboxylic acid component. Examples of the diol component include aliphatic C₂₋₁₂ diols, such as ethylene glycol; polyoxy C₂₋₄ alkylene glycols, such as diethylene glycol; alicyclic C₅₋₁₅ diols, such as cyclohexanedimethanol; and aromatic C₆₋₂₀ diols, such as bisphenol A. Examples of the dicarboxylic acid component include aromatic C₈₋₂₀ dicarboxylic acids, such as terephthalic acid; aliphatic C₂₋₄₀ dicarboxylic acids, such as adipic acid; and alicyclic C₈₋₁₅ dicarboxylic acids, such as cyclohexanedicarboxylic acid. Examples of the polyester resin also include polyesters obtained by polycondensation of oxycarboxylic acid. Examples of the oxycarboxylic acid include aliphatic C₂₋₆ oxycarboxylic acids, such as lactic acid, and aromatic C₇₋₁₀ oxycarboxylic acids, such as hydroxybenzoic acid. Examples of the polyester resin also include polyesters obtained by ring-opening polymerization of lactone. Examples of the lactone include C₄₋₁₂ lactones, such as ϵ-caprolactone, δ-valerolactone, and γ-butyrolactone. Examples of the polyester resin also include polyesters containing a urethane bond obtained by reacting a polyester diol and a diisocyanate. The polyester resin includes a homopolyester and a copolyester. In addition, as the polyester resin, a commercially available product, for example, “Placcel H1P (trade name)” (available from Daicel Corporation) can be used.

Examples of the polyurethane resins may include resins obtained by reaction between a diisocyanate and a polyol, and a chain extender used as necessary. Examples of the diisocyanate include aliphatic diisocyanates, such as hexamethylene diisocyanate; alicyclic diisocyanates, such as isophorone diisocyanate; and aromatic diisocyanates, such as tolylene diisocyanate. Examples of the polyol include polyester diols, polyether diols, and polycarbonate diols. Examples of the chain extender include C₂₋₁₀ alkylene diols, such as ethylene glycol; aliphatic diamines, such as ethylene diamine; alicyclic diamines, such as isophorone diamine; and aromatic diamines, such as phenylene diamine.

Examples of the polyamide resins may include: polyamides obtained by polycondensation of a diamine component and a dicarboxylic acid component; polyamides obtained by polycondensation of an aminocarboxylic acid; polyamides obtained by ring-opening polymerization of a lactam; and polyesteramides obtained by polycondensation of a diamine component, a dicarboxylic acid component, and a diol component. Examples of the diamine component include C₄₋₁₀ alkylene diamines, such as hexamethylene diamine. Examples of the dicarboxylic acid component include C₄₋₂₀ alkylene dicarboxylic acids, such as adipic acid. Examples of the aminocarboxylic acids include C₄₋₂₀ aminocarboxylic acids, such as ω-aminoundecanoic acid. Examples of the lactam include C₄₋₂₀ lactams, such as ω-laurolactam. Examples of the diol component include C₂₋₁₂ alkylene diols, such as ethylene glycol. In addition, the polyamide resins include homopolyamides and copolyamides.

A softening point (T₂) of the thermoplastic resin (C) is preferably at least 10° C. higher than the heat curing temperature of a permanent adhesive described later used in combination with the temporary adhesive containing the thermoplastic resin (C) in the semiconductor device manufacturing method according to an embodiment of the present invention. The difference between the heat curing temperature of the permanent adhesive and T₂ is, for example, from 10 to 40° C. and preferably from 20 to 30° C.

T₂ can be adjusted, for example, by controlling the weight average molecular weight (Mw: by the GPC method calibrated with polystyrene standards) of the thermoplastic resin (C). The weight average molecular weight of the thermoplastic resin (C) is, for example, from 1500 to 100000, preferably from 2000 to 80000, more preferably from 3000 to 50000, more preferably from 10000 to 45000, and more preferably from 15000 to 35000.

In the temporary adhesive containing at least the polyvalent vinyl ether compound (A), the compound (B), and the thermoplastic resin (C) as described above, a softening point (T₃) of the polymer of the polyvalent vinyl ether compound (A) and the compound (B) is at least 10° C. higher than the heat curing temperature of a permanent adhesive described later used in combination with the temporary adhesive in the semiconductor device manufacturing method according to an embodiment of the present invention. The difference between the heat curing temperature of the permanent adhesive and T₃ is, for example, from 10 to 40° C. and preferably from 20 to 30° C.

When the heat curing temperature of the permanent adhesive described later is, for example, 120° C., the content of the polyvalent vinyl ether compound (A) in the temporary adhesive is in an amount where an amount of vinyl ether groups in the polyvalent vinyl ether compound (A) becomes, for example, 0.01 to 10 mol, preferably an amount of 0.05 to 5 mol, more preferably of 0.07 to 1 mol, and more preferably of 0.08 to 0.5 mol, relative to a total amount of 1 mol of hydroxy groups and carboxy groups in the compound (B) in the temporary adhesive.

The content of the thermoplastic resin (C) in the temporary adhesive is, for example, from 0.1 to 3 parts by mass, preferably from 0.2 to 2 parts by mass, and more preferably from 0.3 to 1 part by mass, relative to 1 part by mass of the compound (B) in the temporary adhesive.

The total content of the polyvalent vinyl ether compound (A), the compound (B), and the thermoplastic resin (C) in the temporary adhesive is, for example, from 70 to 99.9 mass %, preferably from 80 to 99 mass %, more preferably from 85 to 95 mass %, and more preferably from 85 to 90 mass % of the total non-volatile content of the temporary adhesive.

The temporary adhesive may further contain a polymerization accelerator. Examples of the polymerization accelerator may include a monovalent carboxylic acid represented by Formula (d) below and a monovalent alcohol represented by

Formula (e) below. One of these polymerization accelerators can be used alone or two or more in combination. The configuration in which the temporary adhesive contains a polymerization accelerator is suitable for accelerating the polymerization reaction of the polyvalent vinyl ether compound (A) and the compound (B). The configuration is suitable for forming a polymer having an equivalent softening point or higher softening point even in lowering the heating temperature during polymerization in comparison with using an adhesive containing no polymerization accelerator and thus is suitable for ensuring adhesiveness in the temporary adhesive 2 in high temperature environments (e.g., approximately from 160 to 180° C.).

Z₃—COOH (d)

(Wherein, Z₃ represents a group that may have a substituent other than a carboxy group, the group in which one hydrogen atom is removed from a structural formula of one selected from the group consisting of saturated or unsaturated aliphatic hydrocarbons, saturated or unsaturated alicyclic hydrocarbons, and aromatic hydrocarbons.)

Z₄—OH (e)

(Wherein, Z₄ represents a group that may have a substituent other than a hydroxy group, the group in which one hydrogen atom is removed from a structural formula of an aromatic hydrocarbon.)

Examples of the saturated or unsaturated aliphatic hydrocarbon, saturated or unsaturated alicyclic hydrocarbon, and aromatic hydrocarbon in Z₃ in Formula (d) above may include saturated or unsaturated aliphatic hydrocarbons, saturated or unsaturated alicyclic hydrocarbons, and aromatic hydrocarbons exemplified for Z₁ in Formula (a) above. Examples of the substituent that may be included in Z₃ may include examples of the substituent that may be included in Z₁ excluding a carboxy group. In addition, examples of the aromatic hydrocarbon in Z₄ in Formula (e) above may include aromatic hydrocarbons exemplified for Z₁ in Formula (a) above. Examples of the substituent that may be included in Z₄ may include examples of the substituent that may be included in Z₁ excluding a hydroxy group.

When a polymerization accelerator is contained in the temporary adhesive, the pKa (acid dissociation constant) of the polymerization accelerator is preferably from 3 to 8 and more preferably from 4 to 6. Such a configuration is suitable for inhibiting unintended polymerization and the resulting increase in viscosity or the like in the temporary adhesive to ensure storage stability, as well as for ensuring the polymerization promoting effect by the polymerization accelerator in forming the temporary adhesive layer 2 from the temporary adhesive.

The monovalent carboxylic acid represented by Formula (d) is preferably compounds (including geometric isomers) shown below.

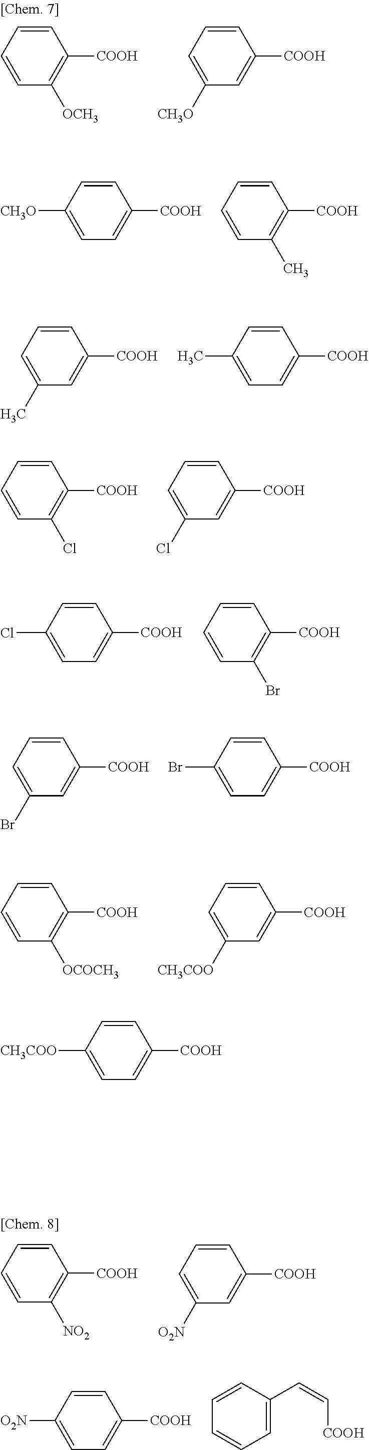

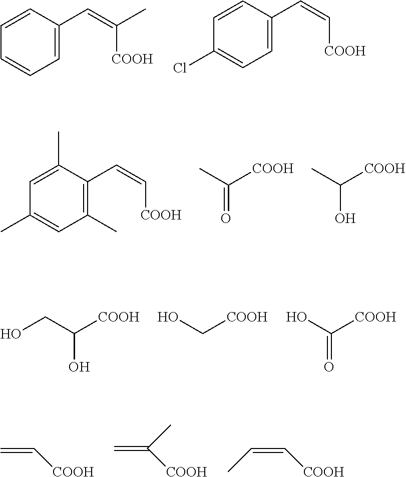

The monovalent alcohol represented by Formula (e) is preferably compounds shown below.

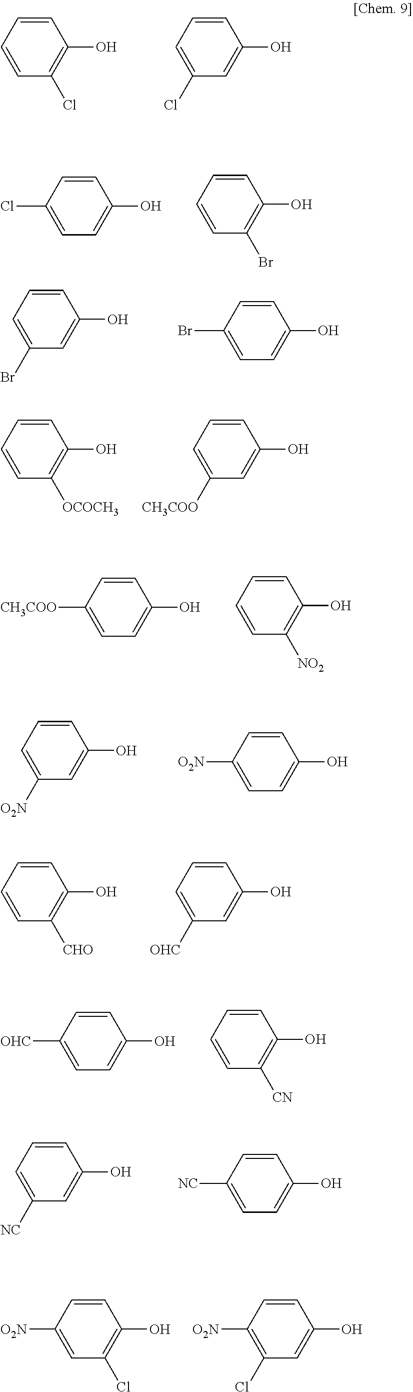

When a polymerization accelerator is contained in the temporary adhesive, the content of the polymerization accelerator is, for example, approximately from 0.01 to 5 parts by mass, preferably from 0.1 to 3 parts by mass, and more preferably from 0.3 to 1 part by mass, relative to 1 part by mass of the polyvalent vinyl ether compound (A) contained in the temporary adhesive.

The temporary adhesive may further contain an antioxidant. The configuration in which the temporary adhesive contains an antioxidant is suitable for preventing oxidation of the compound (B) and the thermoplastic resin (C) described above in the temporary adhesive during heat treatment of the temporary adhesive. The antioxidation of the compound (B) and the thermoplastic resin (C) in the temporary adhesive is suitable for ensuring solubility of a softened composition obtained by heat-treating the temporary adhesive layer 2 formed from the temporary adhesive. Thus, the antioxidation is suitable for removing a glue residue if remains on an adherend, such as a wafer, after peeling the temporary adhesive layer 2 from the adherend through heat treatment.

Examples of the antioxidant may include phenolic antioxidants, phosphorus antioxidants, thioester antioxidants, and amine antioxidants. One of these antioxidants can be used alone or two or more in combination. Phenolic antioxidants have a particularly excellent antioxidant effect during heat treatment and thus are preferred as an antioxidant in the temporary adhesive.

Examples of the phenolic antioxidants may include pentaerythritol tetrakis[3 (3,5 -di-t-butyl-4-hydroxyphenyl)propionate], thiodiethylene bis[3-(3,5-di-t-butyl-4-hydroxyphenyl)propionate], octadecyl 3-(3,5-di-t-butyl-4-hydroxyphenyl)propionate, N,N′-hexamethylene bis[3-(3,5-di-t-butyl-4-hydroxyphenyl)propionamide], octyl 3-(4-hydroxy-3,5-diisopropylphenyl)propionate, 1,3,5 -tri s(4-hydroxy-3,5-di-t-butylbenzyl)-2,4,6-trimethylbenzene, 2,4-bis(dodecylthiomethyl)-6-methylphenol, and calcium bis[3,5-di(t-butyl)-4-hydroxybenzyl(ethoxy)phosphinate]. As the phenolic antioxidant, a commercially available product under the trade name, for example, “Irganox 1010”, “Irganox 1035”, “Irganox 1076”, “Irganox 1098”, “Irganox 1135”, “Irganox 1330”, “Irganox 1726”, or “Irganox 1425WL” (all available from BASF) can be used.

When an antioxidant is contained in the temporary adhesive, the content of the antioxidant is, for example, from 0.01 to 15 parts by mass, preferably from 0.1 to 12 parts by mass, and more preferably from 0.5 to 10 parts by mass, relative to 100 parts by mass of the total of the compound (B) and the thermoplastic resin (C) contained in the temporary adhesive.

The temporary adhesive may further contain additional component as necessary. Examples of the additional component may include an acid generator, a surfactant, a solvent, a leveling agent, a silane coupling agent, and a foaming agent. One of these additional components can be used alone or two or more in combination.

When a surfactant is contained in the temporary adhesive, the content of the surfactant in the temporary adhesive is preferably approximately from 0.01 to 1 mass %. Such a configuration is suitable for preventing repelling during the coating of the temporary adhesive and is suitable for ensuring the uniformity of the coating.

Examples of such a surfactant include products under the trade names “F-444”, “F-447”, “F-554”, “F-556”, and “F-557” (all are fluorine oligomers available from DIC Corporation), a product under the trade name “BYK-350” (an acrylic polymer available from BYK), and products under the trade names “A-1420”, “A-1620”, and “A-1630” (all are fluorine-containing alcohols available from Daikin Industries, Ltd.). One of these surfactants can be used alone or two or more in combination.

The temporary adhesive preferably contains a solvent from the perspective of adjusting the viscosity of the temporary adhesive. Examples of the solvent include toluene, hexane, isopropanol, methyl isobutyl ketone, cyclopentanone, cyclohexanone, propylene glycol monomethyl ether acetate, propylene glycol monomethyl ether, and γ-butyrolactone. One of these solvents can be used alone or two or more in combination. When the temporary adhesive contains a solvent, the solvent content in the temporary adhesive is, for example, from 55 to 80 mass %.

The temporary adhesive can be prepared by stirring and mixing the components while air bubbles are removed under vacuum as necessary. The temperature of the mixture during stirring and mixing is preferably approximately from 10 to 80° C. For stirring and mixing, a rotation-revolution mixer, a single-axis or multi-axis extruder, a planetary mixer, a kneader, or a resolver can be used.

The viscosity of the temporary adhesive (viscosity measured under conditions of 25° C. and a shear rate of 50/s) is, for example, approximately from 30 to 2000 mPa·s, preferably from 300 to 1500 mPa·s, and more preferably from 500 to 1500 mPa·s. Such a configuration is suitable for ensuring the coating properties of the temporary adhesive and uniformly coating the temporary adhesive on the surface of an adherend, such as a wafer.

The temporary adhesive as described above is coated on the surface of an adherend, such as a wafer, and then heat-treated. This allows vinyl ether groups of the polyvalent vinyl ether compound (A) and hydroxy groups and/or carboxy groups of the compound (B) in the temporary adhesive to be bonded with acetal bonds to form a polymer from the polyvalent vinyl ether compound (A) and the compound (B). For example, when temporary adhesive containing a compound represented by Formula (a′) below as the polyvalent vinyl ether compound (A) and containing a compound having a constituent unit represented by Formula (b′) below as the compound (B) is heat-treated to polymerize both compounds, a polymer represented by Formula (P) below is produced.

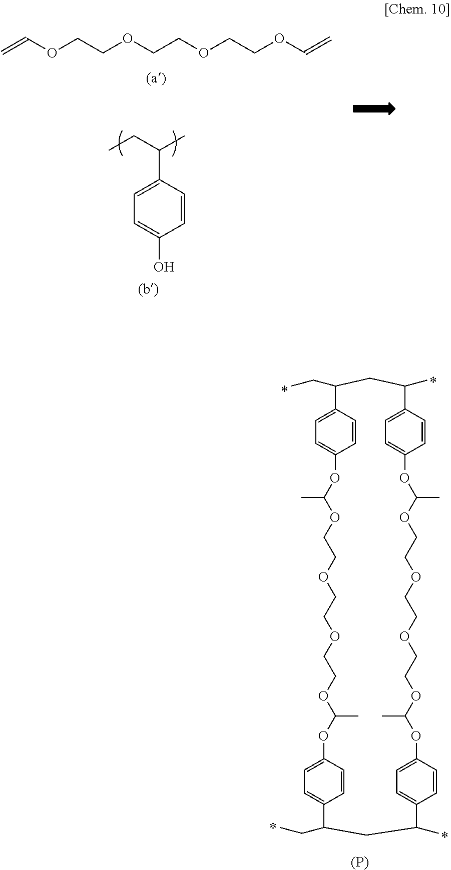

The softening point (T₃) of the polymer obtained by heat-treating the temporary adhesive can be controlled by adjusting the relative amounts of the polyvalent vinyl ether compound (A) and the compound (B). When the heat curing temperature of a permanent adhesive described later used in combination with the temporary adhesive is 120° C., the softening point (T₃) of the polymer is, for example, not lower than 130° C., preferably from 130 to 170° C., and more preferably from 140 to 160° C.

Each softening point of: the polymer of the polyvalent vinyl ether compound (A) and the compound (B), the polyvalent vinyl ether compound (A), the compound (B), and the thermoplastic resin (C) can be measured using a Koka flow tester under the flow conditions below.
Flow conditions
Pressure: 100 kg/cm²
Speed: 6° C./min
Nozzle: 1 mm φ×10 mm

In addition, the softening point of the temporary adhesive layer formed from the temporary adhesive is set to the temperature determined as follows. First, 0.1 g of the temporary adhesive is coated on a first glass plate at a thickness of 10 μm to form a coating of the temporary adhesive. Then, a second glass plate is overlaid on the coating. Then, this is heat-treated to polymerize the polyvalent vinyl ether compound (A) and the compound (B) in the temporary adhesive between the first and second glass plates to cure the temporary adhesive, thus bonding both glass plates via the temporary adhesive. The heat treatment includes, for example, heating at 140° C. for 2 minutes, followed by heating at 200° C. for 2 minutes, and followed by heating at 230° C. for 4 minutes. Such adhesive bonding provides a laminate having a laminated structure of the first glass plate, the second glass plate, and the temporary adhesive layer between the first and second glass plates. For this laminate, in a state where the second glass plate is fixed, the first glass plate is pulled in the horizontal direction (in-plane direction of the glass plate) by applying a stress of 2 kg under heating, and the temperature at which the first glass plate starts to move is measured. The temperature determined as described above is taken as the softening point.

In the present semiconductor device manufacturing method, then, as illustrated in FIG. 1(b), the wafer 1 is thinned in the reinforced wafer 1R (thinning step). Specifically, the wafer 1 in a state of being supported by the supporting substrate S is thinned to a predetermined thickness by grinding from the back surface 1b side of the wafer 1 using a grinder to form a thinned wafer 1T. The thickness of the wafer 1 after thinning (thinned wafer 1T) is, for example, from 1 to 20 μm.

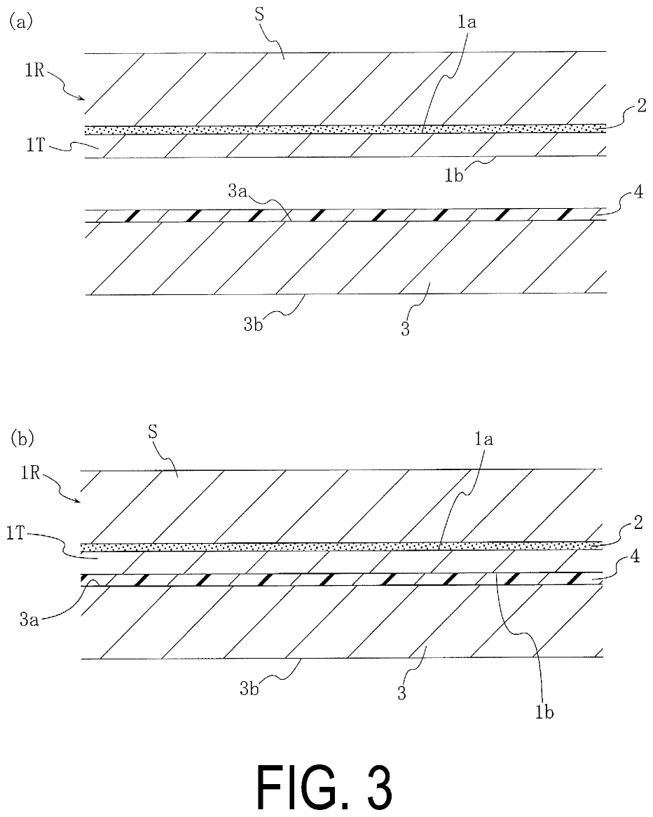

Then, for example, as illustrated in FIG. 3, the thinned wafer 1T side of the reinforced wafer 1R is bonded to a wafer 3, which is a base wafer, via an adhesive 4 (bonding step).

The wafer 3 is a base wafer including a semiconductor wafer main body in which a semiconductor element can be fabricated and includes an element forming surface 3a and a back surface 3b opposite from the element forming surface 3a. As the constituent material for forming the semiconductor wafer main body of the wafer 3, for example, the materials listed above as constituent materials for forming the semiconductor wafer main body of the wafer 1 can be employed. The thickness of the wafer 3, which is the base wafer, is preferably not less than 300 μm, more preferably not less than 500 μm, and more preferably not less than 700 μm from the perspective of ensuring strength of the wafer 3 during the manufacturing process. From the perspective of reducing the grinding time in grinding on the wafer 3, the grinding described later, the thickness of the wafer 3 is preferably not greater than 1000 μm, more preferably not greater than 900 μm, and more preferably not greater than 800 μm.

The adhesive 4 is a thermosetting adhesive for achieving a wafer-to-wafer bonding and preferably contains a polymerizable group-containing polyorganosilsesquioxane (i.e., a polyorganosilsesquioxane having a polymerizable functional group) as a thermosetting resin. The polymerizable functional group contained in the polymerizable group-containing polyorganosilsesquioxane is preferably an epoxy group or a (meth)acryloyloxy group. The polymerizable group-containing polyorganosilsesquioxane is suitable for achieving high heat resistance in an adhesive layer to be formed as well as achieving lower curing temperature for forming the adhesive layer and thus preventing damage to the elements in the wafer as an adherend. The content ratio of the polymerizable group-containing polyorganosilsesquioxane in the adhesive 4 is, for example, not less than 70 mass %, preferably from 80 to 99.8 mass %, and more preferably from 90 to 99.5 mass %. As the thermosetting resin in the adhesive 4, a benzocyclobutene (BCB) resin or a novolac-based epoxy resin may be used instead of the polymerizable group-containing polyorganosilsesquioxane.

In the present embodiment, the polymerizable group-containing polyorganosilsesquioxane contained in the adhesive 4 contains, as siloxane constituent units, a first constituent unit [RSiO_{3/2}] containing at least a constituent unit represented by Formula (1) below and a second constituent unit [RSiO_{2/2}(OR′)] containing at least a constituent unit represented by Formula (2) below (R and R′ in the second constituent unit may be identical or different). These constituent units belong to what are called T units in the siloxane constituent units, and in the present embodiment, the constituent unit [RSiO_{3/2}] is a T3 form, and the constituent unit [RSiO_{2/2}(OR′)] is a T2 form. In the T3 form, the silicon atom is bonded to three oxygen atoms, each oxygen atom also bonded to a silicon atom in another siloxane constituent unit. In the T2 form, the silicon atom is bonded to two oxygen atoms, each oxygen atom also bonded to a silicon atom in another siloxane constituent unit, and bonded to an oxygen of an alkoxy group. Both such a T3 form and a T2 form belong to T units as siloxane constituent units as described above and are partial structures of polymerizable group-containing polyorganosilsesquioxanes that can be formed by hydrolysis of a silane compound having three hydrolyzable functional groups and a subsequent condensation reaction.

### [Chem. 11]

[R¹SiO_{2/3}] (1)

[R²SiO_{2/2}(OR²)] (2)

R¹ in Formula (1) and R¹ in Formula (2) each represent a group containing an epoxy group or a (meth)acryloyloxy group, and R² in Formula (2) represents a hydrogen atom or an alkyl group having from 1 to 4 carbon atoms.

Examples of R¹ in Formula (1) and Formula (2), when each R¹ is an epoxy group-containing group, include groups represented by Formulas (3) to (6) below. Each of R³, R⁴, R⁵, and R⁶ in Formulas (3) to (6) represents a linear or branched alkylene group having, for example, from 1 to 10 carbon atoms. Examples of such an alkylene group include a methylene group, a methylmethylene group, a dimethylmethylene group, an ethylene group, a propylene group, a trimethylene group, a tetramethylene group, a pentamethylene group, a hexamethylene group, and a decamethylene group. From the perspective of achieving high heat resistance and reducing shrinkage during curing in the adhesive layer to be formed from the adhesive 4, each R¹ as an epoxy group-containing group in Formula (1) and Formula (2) is preferably an epoxy group-containing group represented by Formula (3) or an epoxy group-containing group represented by Formula (4) and more preferably a 2-(3,4-epoxycyclohexyl)ethyl group, which is a group represented by Formula (3) where R³ is an ethylene group.

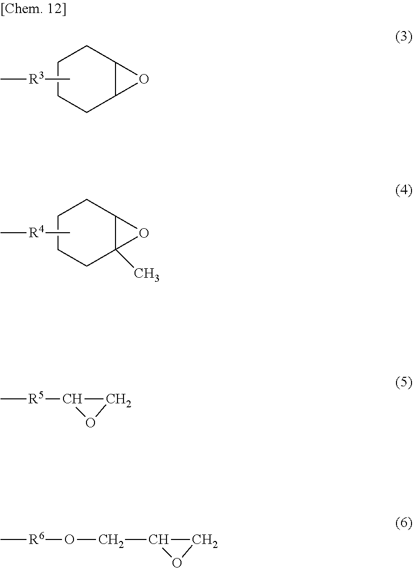

As described above, R² in Formula (2) above represents a hydrogen atom or an alkyl group having from 1 to 4 carbon atoms, and thus, OR² in Formula (2) represents a hydroxy group or an alkoxy group having from 1 to 4 carbon atoms. Examples of the alkoxy group having from 1 to 4 carbon atoms include a methoxy group, an ethoxy group, a propoxy group, an isopropoxy group, a butoxy group, and an isobutyloxy group.

The polymerizable group-containing polyorganosilsesquioxane contained in the adhesive 4 may contain one type of constituent unit represented by Formula (1) above or may contain two or more types. The polymerizable group-containing polyorganosilsesquioxane may contain one type of constituent unit represented by Formula (2) above or may contain two or more types.

The polymerizable group-containing polyorganosilsesquioxane described above contained in the adhesive 4 may contain, as the above T3 form, a constituent unit represented by Formula (7) below in addition to the constituent unit represented by Formula (1). R⁷ in Formula (7) represents a hydrogen atom, a substituted or unsubstituted alkyl group, a substituted or unsubstituted alkenyl group, a substituted or unsubstituted cycloalkyl group, a substituted or unsubstituted aryl group, or a substituted or unsubstituted aralkyl group. IC in Formula (7) is preferably a substituted or unsubstituted alkyl group, a substituted or unsubstituted alkenyl group, or a substituted or unsubstituted aryl group, and more preferably a phenyl group.

### [Chem. 13]

[R⁷SiO_{3/2}] (7)

Examples of the alkyl group described above for R⁷ include a methyl group, an ethyl group, a propyl group, an n-butyl group, an isopropyl group, an isobutyl group, an s-butyl group, a t-butyl group, and an isopentyl group. Examples of the alkenyl group described above for R⁷ include a vinyl group, an allyl group, and an isopropenyl group. Examples of the cycloalkyl group described above for R⁷ include a cyclobutyl group, a cyclopentyl group, and a cyclohexyl group. Examples of the aryl group described above for R⁷ include a phenyl group, a tolyl group, and a naphthyl group. Examples of the aralkyl group described above for R⁷ include a benzyl group and a phenethyl group.

Examples of the substituent of the alkyl group, alkenyl group, cycloalkyl group, aryl group, and aralkyl group described above for R⁷ include: an ether group; an ester group; a carbonyl group; a siloxane group; a halogen atom, such as a fluorine atom; an acryl group; a methacryl group; a mercapto group; an amino group; and a hydroxyl group.

The polymerizable group-containing polyorganosilsesquioxane described above contained in the adhesive 4 may contain, as the above T2 form, a constituent unit represented by Formula (8) below in addition to the constituent unit represented by Formula (2). R⁷ in Formula (8) represents a hydrogen atom, a substituted or unsubstituted alkyl group, a substituted or unsubstituted alkenyl group, a substituted or unsubstituted cycloalkyl group, a substituted or unsubstituted aryl group, or a substituted or unsubstituted aralkyl group and is specifically the same as R⁷ in Formula (7) above. R² in Formula (8) represents a hydrogen atom or an alkyl group having from 1 to 4 carbon atoms and is specifically the same as R² in Formula (2) above.

### [Chem. 14]

[R⁷SiO_{2/2}(OR²)] (8)

The polymerizable group-containing polyorganosilsesquioxane described above contained in the adhesive 4 may contain, in its siloxane constituent unit thereof, at least one type selected from the group consisting of what is called an M unit [R₃SiO_{1/2}], what is called a D unit [R₂SiO_{2/2}], and what is called a Q unit [SiO_{4/2}] in addition to the first and second constituent units described above, which are T units.

The polymerizable group-containing polyorganosilsesquioxane may have any of a cage, incomplete cage, ladder, or random silsesquioxane structure or may have a combined structure of two or more of these silsesquioxane structures.

In all the siloxane constituent units of the polymerizable group-containing polyorganosilsesquioxane in the adhesive 4, the value of the molar ratio of the T3 form to the T2 form (i.e., T3 form/T2 form) is, for example, from 5 to 500, and the lower limit is preferably 10. The upper limit is preferably 100 and more preferably 50. For the polymerizable group-containing polyorganosilsesquioxane, adjustment of the value of [T3 form/T2 form] to the range improves compatibility with components other than the polymerizable group-containing polyorganosilsesquioxane contained in the adhesive 4, improving handleability. The value of [T3 form/T2 form] in the polymerizable group-containing polyorganosilsesquioxane of 5 to 500 means that the presence amount of the T2 form is relatively small relative to the T3 form, and the hydrolysis and the condensation reaction of silanol are more advanced.

The value of the molar ratio (T3 form/T2 form) in the polymerizable group-containing polyorganosilsesquioxane can be determined, for example, by ²⁹Si—NMR spectroscopy measurements. In the ²⁹Si—NMR spectrum, the silicon atom in the first constituent unit (T3 form) described above and the silicon atom in the second constituent unit (T2 form) described above indicate peaks or signals with different chemical shifts. The value of the molar ratio can be determined from the area ratio of these peaks. The ²⁹Si—NMR spectrum of the polymerizable group-containing polyorganosilsesquioxane can be measured, for example, with the following instrument according to the following conditions.

Measuring instrument: “JNM-ECA500NMR (trade name)” (available from JEOL Ltd.)
Solvent: Deuterochloroform
Number of accumulation: 1800 scans
Measurement temperature: 25° C.

The number average molecular weight (Mn) of the polymerizable group-containing polyorganosilsesquioxane contained in the adhesive 4 is preferably from 1000 to 50000, more preferably from 1500 to 10000, more preferably from 2000 to 8000, and more preferably from 2000 to 7000. The polymerizable group-containing polyorganosilsesquioxane with a number average molecular weight of not lower than 1000 improves insulating properties, heat resistance, crack resistance, and adhesiveness of a cured product or the adhesive layer to be formed. On the other hand, the polymerizable group-containing polyorganosilsesquioxane with a molecular weight of not higher than 50000 improves compatibility of the polymerizable group-containing polyorganosilsesquioxane in the adhesive 4 with other components and improves insulating properties, heat resistance, and crack resistance of a cured product or the adhesive layer to be formed.

The molecular weight dispersity (Mw/Mn) of the polymerizable group-containing polyorganosilsesquioxane contained in the adhesive 4 is preferably from 1.0 to 4.0, more preferably from 1.1 to 3.0, and more preferably from 1.2 to 2.7. The polymerizable group-containing polyorganosilsesquioxane with a molecular weight dispersity of not greater than 4.0 further increases heat resistance, crack resistance, and adhesiveness of a cured product or the adhesive layer to be formed. On the other hand, the polymerizable group-containing polyorganosilsesquioxane with a molecular weight dispersity of not less than 1.0 allows the adhesive composition to easily become liquid, tending to improve its handleability.

The number average molecular weight (Mn) and the weight average molecular weight (Mw) of the polymerizable group-containing polyorganosilsesquioxane are values determined by gel permeation chromatography (GPC) and calculated by polystyrene standards. The number average molecular weight (Mn) and the weight average molecular weight (Mw) of the polymerizable group-containing polyorganosilsesquioxane can be measured using, for example, an HPLC instrument (“LC-20AD (trade name)” available from Shimadzu Corporation) according to the following conditions.

Column: Two Shodex KF-801 (upstream side, available from Showa Denko K.K.), Shodex KF-802 (available from Showa Denko K.K.), and Shodex KF-803 (downstream side, available from Showa Denko K.K.) are connected in series
Measurement temperature: 40° C.
Eluent: Tetrahydrofuran (THF)
Sample concentration: From 0.1 to 0.2 mass %
Flow rate: 1 mL/min
Standard sample: Polystyrene
Detector: A UV-VIS detector (“SPD-20A (trade name)” available from Shimadzu Corporation)

The polymerizable group-containing polyorganosilsesquioxane as described above can be manufactured by hydrolysis of a silane compound having three hydrolyzable functional groups and a subsequent condensation reaction. The raw material used in the manufacturing includes at least a compound represented by Formula (9) below and, as necessary, a compound represented by Formula (10) below. The compound represented by Formula (9) is for forming the constituent unit represented by Formula (1) above and the constituent unit represented by Formula (2) above. The compound represented by Formula (10) is for forming the constituent unit represented by Formula (7) above and the constituent unit represented by Formula (8) above.

### [Chem. 15]

R¹SiX¹₃ (9)

R⁷SiX²₃ (10)

R¹ in Formula (9) represents a group containing a polymerizable group and is specifically the same as R¹ in Formulas (1) and (2) above. X¹ in Formula (9) represents an alkoxy group or a halogen atom. Examples of the alkoxy group include alkoxy groups having from 1 to 4 carbon atoms, such as a methoxy group, an ethoxy group, a propoxy group, an isopropyloxy group, a butoxy group, and an isobutyloxy group. Examples of the halogen atom as X¹ include a fluorine atom, a chlorine atom, a bromine atom, and an iodine atom. X¹ is preferably an alkoxy group and more preferably a methoxy group or an ethoxy group. In Formula (9), three X¹'s may be identical or different from each other.

R⁷ in Formula (10) represents a substituted or unsubstituted aryl group, a substituted or unsubstituted aralkyl group, a substituted or unsubstituted cycloalkyl group, a substituted or unsubstituted alkyl group, or a substituted or unsubstituted alkenyl group and is specifically the same as R⁷ in Formulas (7) and (8) above. X² in Formula (10) represents an alkoxy group or a halogen atom and is specifically the same as X¹ in Formula (9) above.

The raw material used in the manufacturing of the polymerizable group-containing polyorganosilsesquioxane described above may further contain an additional hydrolyzable silane compound. Examples of such a compound include a hydrolyzable trifunctional silane compound other than the compounds represented by Formulas (9) and (10) above, a hydrolyzable monofunctional silane compound that is to form an M unit, a hydrolyzable bifunctional silane compound that is to form a D unit, and a hydrolyzable tetrafunctional silane compound that is to form a Q unit.

The amount of the hydrolyzable silane compound as the raw material to be used and its composition is appropriately adjusted according to a structure of the polymerizable group-containing polyorganosilsesquioxane to be manufactured. For example, the amount of the compound represented by Formula (9) above to be used is, for example, from 55 to 100 mol % and preferably from 65 to 100 mol % relative to the total amount of the hydrolyzable silane compound to be used. The amount of the compound represented by Formula (10) above to be used is, for example, from 0 to 70 mol % relative to the total amount of the hydrolyzable silane compound to be used. The total amount of the compound represented by Formula (9) and the compound represented by Formula (10) to be used relative to the total amount of the hydrolyzable silane compound to be used is, for example, from 60 to 100 mol %, preferably from 70 to 100 mol %, and more preferably from 80 to 100 mol %.

In using two or more types of hydrolysable silane compounds in the manufacturing of the polymerizable group-containing polyorganosilsesquioxane, the hydrolysis and the condensation reaction for each type of hydrolyzable silane compound can be performed simultaneously or sequentially.

The hydrolysis and the condensation reaction described above are preferably performed in the presence of one type or two or more types of solvents. Examples of a preferred solvent include ethers, such as diethyl ether, dimethoxyethane, tetrahydrofuran, and dioxane; and ketones, such as acetone, methyl ethyl ketone, and methyl isobutyl ketone. The amount of the solvent to be used is appropriately adjusted according to the reaction time and the like within a range of, for example, not greater than 2000 parts by mass per 100 parts by mass of the hydrolyzable silane compound.

The hydrolysis and the condensation reaction described above are preferably allowed to proceed in the presence of one type or two or more types of catalysts and water. The catalyst may be an acid catalyst or may be an alkali catalyst. The amount of the catalyst to be used is appropriately adjusted within a range of, for example, 0.002 to 0.2 mol per mol of the hydrolyzable silane compound. The amount of the water to be used is appropriately adjusted within a range of, for example, 0.5 to 20 mol per mol of the hydrolyzable silane compound.

The hydrolysis and the condensation reaction of the hydrolyzable silane compound may be performed in one stage or may be performed in two or more stages. In manufacturing the polymerizable group-containing polyorganosilsesquioxane having a value of the molar ratio (T3 form/T2 form) of not less than 5, the reaction temperature of the hydrolysis and the condensation reaction in the first stage is, for example, from 40 to 100° C. and preferably from 45 to 80° C. The reaction time of the hydrolysis and the condensation reaction in the first stage is, for example, from 0.1 to 10 hours and preferably from 1.5 to 8 hours. The reaction temperature of the hydrolysis and the condensation reaction in the second stage is preferably from 5 to 200° C. and more preferably from 30 to 100° C. Control of the reaction temperature in the above range tends to enable more efficient control of the value of the molar ratio (T3 form/T2 form) and the number average molecular weight in the desired ranges. In addition, the reaction time of the hydrolysis and the condensation reaction in the second stage is not particularly limited but is preferably from 0.5 to 1000 hours and more preferably from 1 to 500 hours. Furthermore, the hydrolysis and the condensation reaction described above can be performed under normal pressure, under increased pressure, or under reduced pressure. The hydrolysis and the condensation reaction described above is preferably performed under an atmosphere of an inert gas, such as nitrogen or argon.

The hydrolysis and the condensation reaction of the hydrolyzable silane compound as described above provide the polymerizable group-containing polyorganosilsesquioxane described above. After the completion of the reaction, the catalyst is preferably neutralized to prevent ring-opening of the polymerizable group. The polymerizable group-containing polyorganosilsesquioxane thus obtained is purified as necessary.

The adhesive 4 preferably contains at least one type of curing catalyst in addition to the polymerizable group-containing polyorganosilsesquioxane, for example, manufactured as described above.

Examples of the curing catalyst, when the adhesive 4 contains an epoxy group-containing polyorganosilsesquioxane, include thermal cationic polymerization initiators. Examples of the curing catalyst, when the adhesive 4 contains a (meth)acryloyloxy group-containing polyorganosilsesquioxane, include thermal radical polymerization initiators. The content of the curing catalyst in the adhesive 4 is preferably from 0.1 to 3.0 parts by mass per 100 parts by mass of the polymerizable group-containing polyorganosilsesquioxane.

Examples of the thermal cationic polymerization initiator described above include various types of thermal cationic polymerization initiators, such as arylsulfonium salts, aluminum chelates, and boron trifluoride amine complexes.

Examples of the arylsulfonium salts include hexafluoroantimonate salts. Examples of the aluminum chelates include ethyl acetoacetate aluminum diisopropylate and aluminum tris(ethyl acetoacetate). Examples of the boron trifluoride amine complexes include a boron trifluoride monoethyl amine complex, a boron trifluoride imidazole complex, and a boron trifluoride piperidine complex.

Examples of the thermal radical polymerization initiators described above include thermal radical polymerization initiators of types, such as azo compounds and peroxides. Examples of the azo compounds include 2,2′-azobisisobutyronitrile, 2,2′-azobis(2,4-dimethylvaleronitrile), 2,2′-azobis(4-methoxy-2,4-dimethylvaleronitrile), dimethyl-2,2′-azobis(2-methylpropionate), dimethyl 2,2′-azobis(isobutyrate), diethyl-2,2′-azobis(2-methylpropionate), and dibutyl-2,2′-azobis(2-methylpropionate). Examples of the peroxides include benzoyl peroxide, t-butyl peroxy-2-ethylhexanoate, 2,5-dimethyl-2,5-di(2-ethylhexanoyl) peroxyhexane, t-butyl peroxybenzoate, t-butyl peroxide, cumene hydroperoxide, dicumyl peroxide, di-t-butyl peroxide, 2,5-dimethyl-2,5-dibutyl peroxyhexane, 2,4-dichlorobenzoyl peroxide, 1,4-di(2-t-butylperoxyisopropyl) benzene, 1,1-bis(t-butylperoxy)-3,3,5-trimethylcyclohexane, methyl ethyl ketone peroxide, and 1,1,3,3-tetramethylbutyl peroxy-2-ethylhexanoate.

The adhesive 4 may contain one type or two or more types of additional curable compounds in addition to the polymerizable group-containing polyorganosilsesquioxane described above. Examples of the curable compound include epoxy compounds other than the polymerizable group-containing polyorganosilsesquioxane described above, (meth)acryloyloxy group-containing compounds, vinyl group-containing compounds, oxetane compounds, and vinyl ether compounds.

Examples of the epoxy compounds other than the polymerizable group-containing polyorganosilsesquioxane described above include alicyclic epoxy compounds (alicyclic epoxy resins), aromatic epoxy compounds (aromatic epoxy resins), and aliphatic epoxy compounds (aliphatic epoxy resins). Examples of the alicyclic epoxy compounds include 3,4,3′,4′-diepoxybicyclohexane, 2,2-bis(3,4-epoxycyclohexyl)propane, 1,2-bis(3,4-epoxycyclohexyl)ethane, 2,3-bis(3,4-epoxycyclohexyl)oxirane, bis(3,4-epoxycyclohexylmethyl)ether, and an 1,2-epoxy-4-(2-oxiranyl)cyclohexane adduct of 2,2-bis(hydroxymethyl)-1-butanol (e.g., “EHPE3150” available from Daicel Corporation).

Examples of the aromatic epoxy compounds include epibis-type glycidyl ether epoxy resins and novolac-alkyl-type glycidyl ether epoxy resins.

Examples of the aliphatic epoxy compounds include glycidyl ethers of a q-hydric alcohol (q is a natural number) having no cyclic structure, glycidyl esters of a monocarboxylic acid or a polycarboxylic acid, and epoxy compounds of fat and oil having a double bond. Examples of the epoxy compounds of fat and oil having a double bond include epoxidized linseed oil, epoxidized soybean oil, and epoxidized castor oil.

Examples of the (meth)acryloyloxy group-containing compounds described above include trimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, dipentaerythritol hexa(meth)acrylate, glycerin tri(meth)acrylate, tris(2-hydroxyethyl) isocyanurate tri(meth)acrylate, ethylene glycol di(meth)acrylate, 1,3-butanediol di(meth)acrylate, 1,4-butanediol di(meth)acrylate, 1,6-hexanediol di(meth)acrylate, neopentyl glycol di(meth)acrylate, diethylene glycol di(meth)acrylate, triethylene glycol di(meth)acrylate, dipropylene glycol di(meth)acrylate, bis(2-hydroxyethyl) isocyanurate di(meth)acrylate, dicyclopentanyl diacrylate, epoxy acrylate, urethane acrylate, unsaturated polyester, polyester acrylate, polyether acrylate, vinyl acrylate, silicone acrylate, and polystyrylethyl methacrylate. In addition, examples of the (meth)acryloyloxy group-containing compounds described above also include “DA-141” available from Nagase ChemteX Corporation, “Aronix M-211B” and “Aronix M-208” available from Toagosei Co., Ltd., and “NK Ester”, “ABE-300”, “A-BPE-4”, “A-BPE-10”, “A-BP E-20”, “A-BPE-30”, “BPE-100”, “BPE-200”, “BPE-500”, “BPE-900”, and “BPE-1300N” available from Shin-Nakamura Chemical Co., Ltd.

Examples of the vinyl group-containing compounds include styrene and divinylbenzene.

Examples of the oxetane compounds include 3,3-bis(vinyloxymethyl)oxetane, 3-ethyl-3-(hydroxymethyl)oxetane, 3-ethyl-3-(2-ethylhexyloxymethyl)oxetane, 3-ethyl-3-(hydroxymethyl)oxetane, 3-ethyl-3-[(phenoxy)methyl]oxetane, 3-ethyl-3-(hexyloxymethyl)oxetane, 3-ethyl-3-(chloromethyl)oxetane, and 3,3-bis(chloromethyl)oxetane.

Examples of the vinyl ether compounds include 2-hydroxyethyl vinyl ether, 3-hydroxypropyl vinyl ether, 2-hydroxypropyl vinyl ether, 2-hydroxyisopropyl vinyl ether, 4-hydroxybutyl vinyl ether, 3-hydroxybutyl vinyl ether, 2-hydroxybutyl vinyl ether, 3-hydroxyisobutyl vinyl ether, 2-hydroxyisobutyl vinyl ether, 1-methyl-3-hydroxypropyl vinyl ether, 1-methyl-2-hydroxypropyl vinyl ether, 1-hydroxymethylpropyl vinyl ether, 4-hydroxycyclohexyl vinyl ether, 1,6-hexanediol monovinyl ether, 1,6-hexanediol divinyl ether, 1,8-octanediol divinyl ether, p-xylene glycol monovinyl ether, p-xylene glycol divinyl ether, m-xylene glycol monovinyl ether, m-xylene glycol divinyl ether, o-xylene glycol monovinyl ether, o-xylene glycol divinyl ether, diethylene glycol monovinyl ether, diethylene glycol divinyl ether, triethylene glycol monovinyl ether, and triethylene glycol divinyl ether.

The adhesive 4 preferably contains a solvent to adjust its coating properties or the like. Examples of the solvent include propylene glycol monomethyl ether acetate, methyl ethyl ketone, methyl isobutyl ketone, cyclohexanone, toluene, xylene, ethyl acetate, butyl acetate, 3-methoxybutyl acetate, methoxypropyl acetate, ethylene glycol monomethyl ether acetate, methanol, ethanol, isopropyl alcohol, 1-butanol, 1-methoxy-2-propanol, 3-methoxybutanol, ethoxyethanol, diisopropyl ether, ethylene glycol dimethyl ether, and tetrahydrofuran.

The adhesive 4 may further contain an additive of various types, such as a silane coupling agent, an antifoaming agent, an antioxidant, an antiblocking agent, a leveling agent, a surfactant, an extender, an anticorrosive agent, an antistatic agent, and a plasticizer.

With regard to the heat resistance of the adhesive 4, the pyrolysis temperature of the adhesive 4 is preferably not lower than 200° C., more preferably not lower than 260° C., and more preferably not lower than 300° C. The pyrolysis temperature is a temperature in a curve obtained by thermogravimetric analysis performed using a differential thermal-thermogravimetric simultaneous analyzer, that is, a curve representing temperature dependence of thermal gravity in a predetermined temperature range for a sample to be analyzed, the temperature indicated by a point of intersection of a tangent to a portion where there is no weight loss or the weight is gradually decreasing at a constant rate at the initial temperature increasing process and a tangent at an inflection point within a portion where a significant weight loss is occurring at the middle temperature increasing process subsequent to the initial temperature increasing process. As the differential thermal-thermogravimetric simultaneous analyzer, for example, “TG-DTA6300 (trade name)” available from Seiko Instruments Inc. can be used.

In the bonding step according to the present semiconductor device manufacturing method, the element forming surface 3a side of the wafer 3 is bonded via the adhesive 4 as described above to the back surface 1b side of the thinned wafer 1T in the reinforced wafer 1R.

Specifically, first, the adhesive 4 is coated by spin coating on one or both surfaces to be bonded (the element forming surface 3a of the wafer 3, the back surface 1b of the thinned wafer 1T) to form an adhesive layer. FIG. 3(a) illustrates by way of example coating the adhesive 4 on the element forming surface 3a of the wafer 3. In addition, prior to the coating of the adhesive 4, one or both surfaces to be bonded may be treated with a silane coupling agent. Then, the adhesive 4 (adhesive layer) is dried and solidified by heating. The heating temperature in the heating is, for example, from 50 to 150° C., and the heating time is, for example, from 5 to 120 minutes. The heating temperature may be constant or may be changed stepwise. Then, the surfaces to be bonded are affixed via the adhesive 4 (adhesive layer). In this affixing, the pressure is, for example, from 300 to 5000 g/cm², and the temperature is, for example, from 30 to 200° C. and preferably in a range of not lower than room temperature and not higher than 80° C. Thereafter, the adhesive 4 is cured by heating between the surfaces to be bonded. The heating temperature for curing is, for example, from 30 to 200° C. and preferably from 50 to 190° C. The heating time for curing is, for example, from 5 to 120 minutes. The heating temperature may be constant or may be changed stepwise. The thickness of the adhesive layer after curing the adhesive 4 is, for example, from 0.5 to 20 μm. The above configuration of curing the adhesive 4 at a relatively low temperature in the present step to achieve adhesive bonding is suitable for reducing dimensional change of the adhesive 4 interposed between the wafers during affixing and also suitable for preventing damage to the elements in the wafer as an adherend.

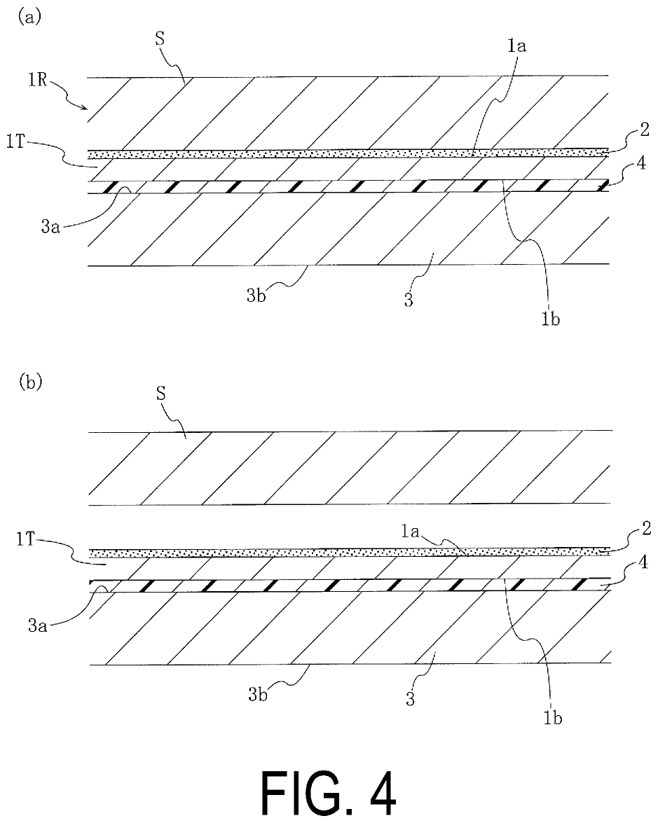

In the present semiconductor device manufacturing method, then, as illustrated in FIGS. 4(a) and 4(b), the temporary adhesion by the temporary adhesive layer 2 between the supporting substrate S and the thinned wafer 1T in the reinforced wafer 1R is released to remove the supporting substrate S (removing step). The removing step preferably includes softening treatment to soften the temporary adhesive layer 2 at a temperature higher than the softening point (T₃) of the polymer described above in the temporary adhesive layer 2, that is, the polymer of the polyvalent vinyl ether compound (A) and the compound (B). The heating temperature of the temporary adhesive layer in this softening treatment is preferably not lower than 170° C., and, for example, not higher than 250° C., preferably not higher than 240° C., and more preferably not higher than 230° C. In the present removing step, for example, after such softening treatment, the supporting substrate S is slid relative to the wafer 1, and the supporting substrate S is separated or removed. After removing the reinforced wafer 1R, if the temporary adhesive remains on the wafer 1, the temporary adhesive is removed. In this removing operation, one type or two or more types of solvents in which the temporary adhesive is readily soluble can be used. Examples of such solvents include cyclohexanone, propylene glycol monomethyl ether, propylene glycol monomethyl ether acetate, acetone, ethyl acetate, butyl acetate, and methyl isobutyl ketone. For the wafer 1 in the reinforced wafer 1R described above not including a wiring structure including an insulating film or a wiring pattern on the element forming surface 1a side of the wafer 1, a wiring structure is formed on the element forming surface 1a of the thinned wafer 1T after the present removing step. The same applies after the removing step described below.

In the semiconductor device manufacturing method of the present embodiment, a predetermined number of the reinforced wafers 1R (illustrated in FIG. 1(a)) are additionally prepared separately from the reinforced wafer 1R described above. As described above, the reinforced wafer 1R has a laminated structure including: the wafer 1 including the element forming surface 1a and the back surface 1b; the supporting substrate S; and the temporary adhesive layer 2 between the wafer 1 and the supporting substrate S. The temporary adhesive layer 2 is formed from the temporary adhesive described above. Then, in each reinforced wafer 1R, the wafer 1 is thinned as illustrated in FIG. 1(b). Specifically, in each reinforced wafer 1R, the wafer 1 in a state of being supported by the supporting substrate S is thinned to a predetermined thickness by grinding from the back surface 1b side of the wafer 1 using a grinder to form a thinned wafer 1T. The thickness of the wafer 1 after thinning (thinned wafer 1T) is, for example, from 1 to 20 μm.

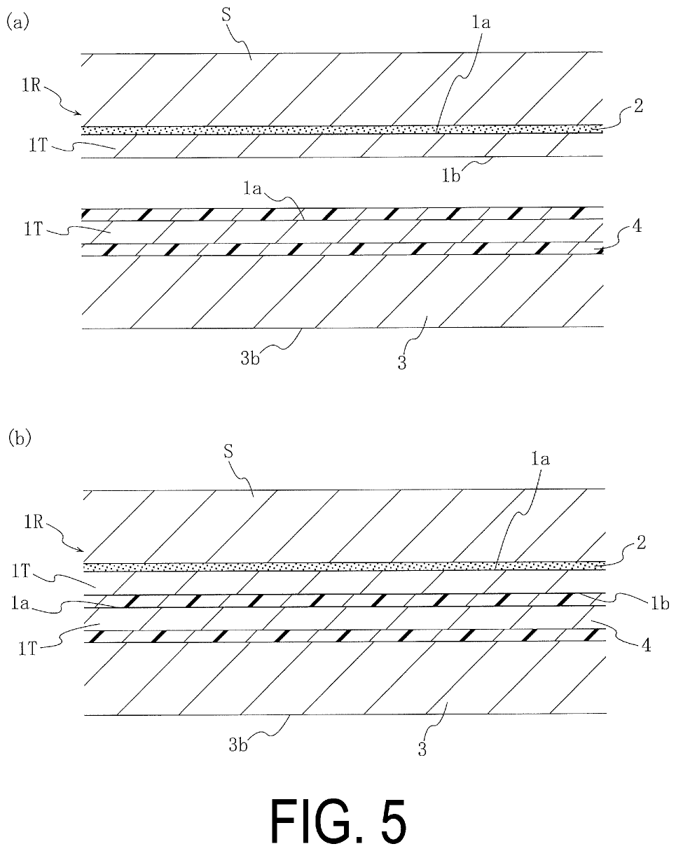

Then, as illustrated in FIGS. 5(a) and 5(b), the element forming surface 1a side of the thinned wafer 1T laminated on the wafer 3, which is the base wafer, is bonded via the adhesive 4 described above to the back surface 1b side of the thinned wafer 1T in the additional reinforced wafer 1R (additional bonding step).

Specifically, first, the adhesive 4 is coated by spin coating on one or both surfaces to be bonded (the element forming surface 1a of one thinned wafer 1T, the back surface 1b of the other thinned wafer 1T) to form an adhesive layer. FIG. 5(a) illustrates by way of example coating the adhesive 4 on the element forming surface 1a of one thinned wafer 1T. In addition, prior to the coating of the adhesive 4, one or both surfaces to be bonded may be treated with a silane coupling agent. Then, the adhesive 4 (adhesive layer) is dried and solidified by heating. The heating temperature in the heating is, for example, from 50 to 150° C., and the heating time is, for example, from 5 to 120 minutes. The heating temperature may be constant or may be changed stepwise. Then, the surfaces to be bonded are affixed via the adhesive 4 (adhesive layer). In this affixing, the pressure is, for example, from 300 to 5000 g/cm², and the temperature is, for example, from 30 to 200° C. and preferably in a range of not lower than room temperature and not higher than 80° C. Thereafter, the adhesive 4 is cured by heating between the surfaces to be bonded. The heating temperature for curing is, for example, from 30 to 200° C. and preferably from 50 to 190° C., and the heating time for curing is, for example, from 5 to 120 minutes. The heating temperature may be constant or may be changed stepwise. The thickness of the adhesive layer after curing the adhesive 4 is, for example, from 0.5 to 20 μm. The above configuration of curing the adhesive 4 at a relatively low temperature in the present additional bonding step to achieve adhesive bonding is suitable for reducing dimensional change of the adhesive 4 interposed between the wafers during affixing and also suitable for preventing damage to the elements in the wafer as an adherend.

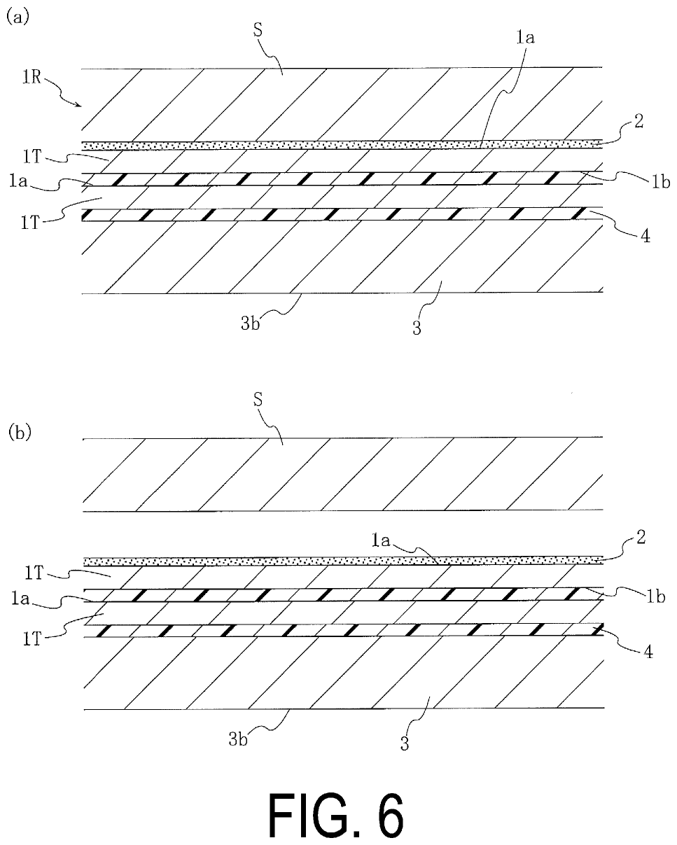

In the present semiconductor device manufacturing method, then, as illustrated in FIGS. 6(a) and 6(b), the temporary adhesion by the temporary adhesive layer 2 between the supporting substrate S and the thinned wafer 1T in the reinforced wafer 1R further laminated is released to remove the supporting substrate S (removing step after the additional bonding step). The present step preferably includes softening treatment to soften the temporary adhesive layer 2 at a temperature higher than the softening point (T₃) of the polymer described above in the temporary adhesive layer 2, that is, the polymer of the polyvalent vinyl ether compound (A) and the compound (B). The heating temperature of the temporary adhesive layer in this softening treatment is preferably not lower than 170° C., and, for example, not higher than 250° C., preferably not higher than 240° C., and more preferably not higher than 230° C. In the present step, for example, after such softening treatment, the supporting substrate S is slid relative to the wafer 1, and the supporting substrate S is separated or removed. After removing the reinforced wafer 1R, if the temporary adhesive remains on the wafer 1, the temporary adhesive is removed.

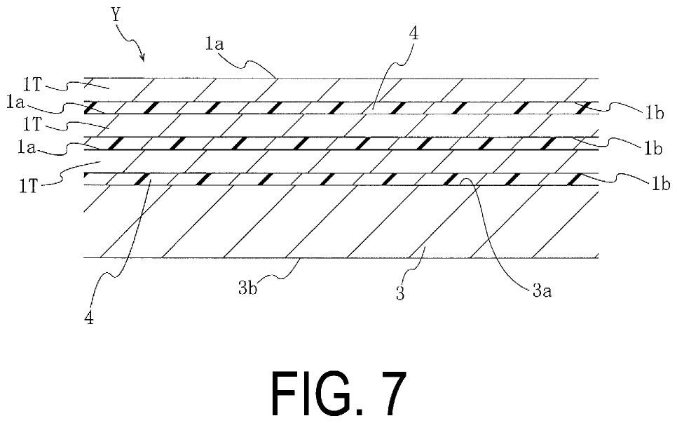

In the present semiconductor device manufacturing method, a plurality of thinned wafers 1T can be sequentially laminated to form a wafer laminate Y (wafer laminate forming step) by repeating, for each additional reinforced wafer 1R to be prepared, a series of processes including a thinning step to thin the wafer 1 of the reinforced wafer 1R (FIG. 1), the additional bonding step described above (FIG. 5), and the subsequent removing step (FIG. 6). In the wafer laminate forming step, at least two wafer laminates Y are formed. The number of wafer lamination may be the same or different between the wafer laminates Y. FIG. 7 illustrates as an example of the wafer laminate Y having a configuration in which three thinned wafers 1T are arranged in multiple layers on the wafer 3.

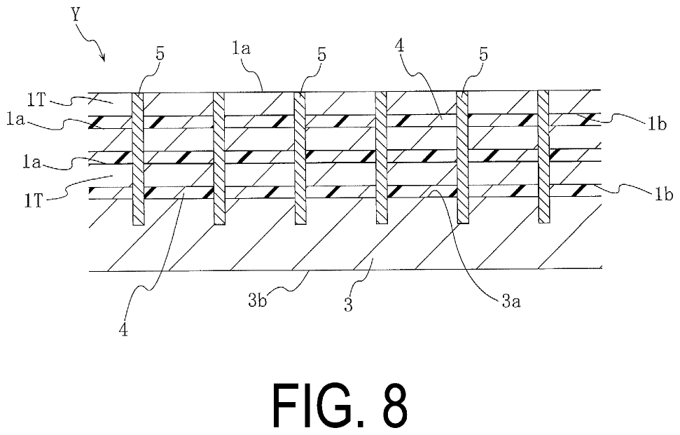

Next, as illustrated in FIG. 8, through electrodes 5 are formed in each wafer laminate Y (electrode forming step). The through electrodes 5 are for electrically connecting semiconductor elements formed in different wafers in the wafer laminate Y. The through electrodes 5 extend through the inside of the wafer laminate Y from the element forming surface 1a of the thinned wafer 1T (first wafer) located at one end of the wafer laminate Y in a lamination direction to a position exceeding the element forming surface 3a of the wafer 3 (second wafer) located at the other end of the wafer laminate Y. In this step, the through electrodes 5 can be formed, for example, by forming openings passing through all of the thinned wafers 1T and the adhesives 4 (adhesive layers) and penetrating into the wafer 3; forming insulating films (not illustrated) on inner wall surfaces of the openings; forming barrier layers (not illustrated) on the insulating film surfaces; forming seed layers (not illustrated) for electroplating on the barrier layer surfaces; and filling the openings with a conductive material, such as copper, by an electroplating method. Examples of the technique for forming the openings include reactive ion etching. In addition, a technique described, for example, in JP 2016-004835 A may be employed to form the through electrodes 5. The through electrodes 5 to be formed electrically connect specifically wiring structures (not illustrated) each formed on the element forming surface 1a side of each thinned wafer 1T and a wiring structure (not illustrated) formed on the element forming surface 3a side of the wafer 3 to each other. Such through electrodes 5 can appropriately electrically connect the semiconductor elements at short distances in a semiconductor device to be manufactured. Thus, the configuration of forming such through electrodes 5 is suitable for achieving an efficient digital signal processing, for reducing attenuation of the high-frequency signal, and also for reducing power consumption in a semiconductor device to be manufactured.

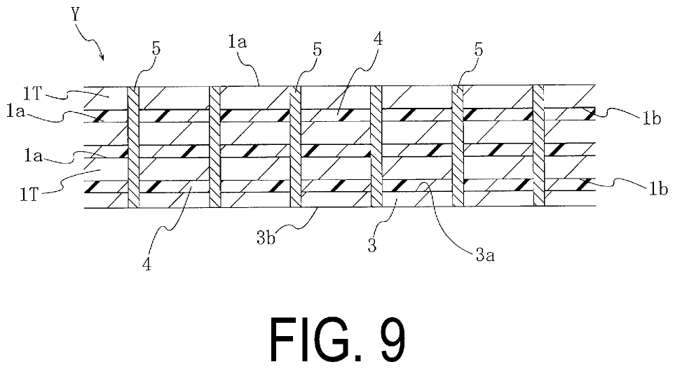

In the present semiconductor device manufacturing method, as illustrated in FIG. 9, the wafer 3 is thinned by grinding the back surface 3b side of the wafer 3 in each wafer laminate Y, and thereby the through electrodes 5 are exposed on the back surface 3b side of the wafer 3 (electrode end part exposing step). The thickness of the wafer 3 after thinning is, for example, from 5 to 200 μm. In the wafer laminate Y that has been subjected to the present step, the through electrodes 5 are exposed at the element forming surface 1a of the thinned wafer 1T (first wafer) located at one end in the wafer lamination direction and are exposed at the back surface 3b of the wafer 3 (second wafer) located at the other end in the wafer lamination direction.

In the present semiconductor device manufacturing method, next, two wafer laminates Y that have been subjected to the electrode end part exposing step are laminated and bonded while electrically connecting the through electrodes 5 between the wafer laminates Y (multilayering step).

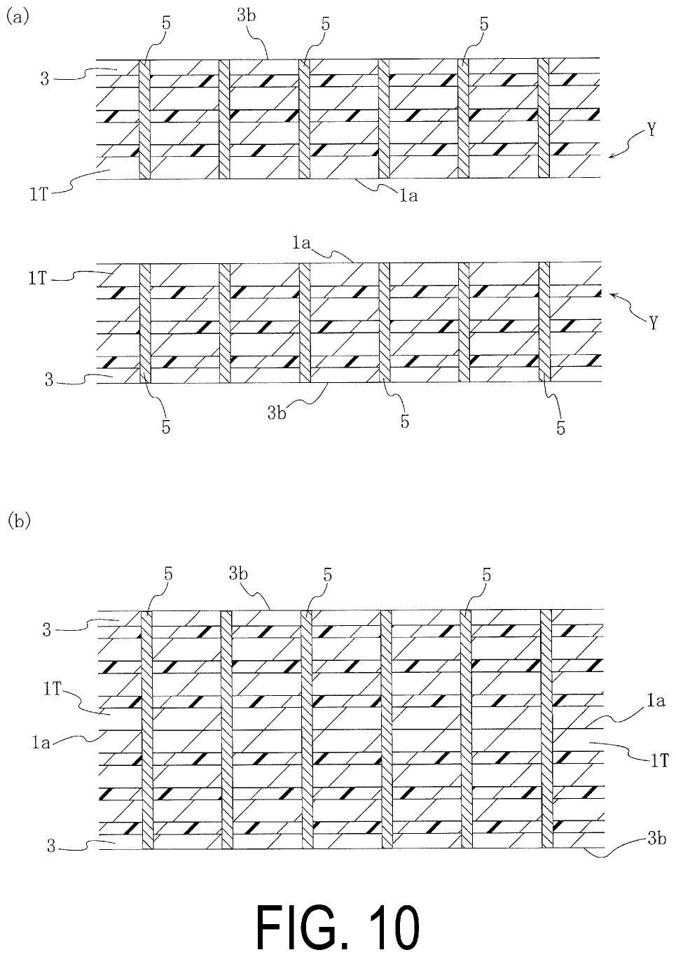

In the multilayering step, as illustrated in FIG. 10, the element forming surface la side of the thinned wafer 1T (first wafer) in one wafer laminate Y to be bonded may be bonded to the element forming surface 1a side of the thinned wafer 1T (first wafer) of another wafer laminate Y (face-to-face bonding between wafer laminates). Examples of the bonding technique include bump bonding in which bumps are interposed between the through electrodes 5 of one wafer laminate Y and the through electrodes 5 of the other wafer laminate Y, and what is called direct bonding. Examples of the direct bonding include inter-electrode direct bonding, such as, for example, Cu—Cu bonding between Cu electrodes (the same applies to a bonding technique in the bonding step between wafer laminates described below). FIG. 10 illustrates, as an example, a case of face-to-face bonding of the wafer laminates Y to each other by direct bonding.

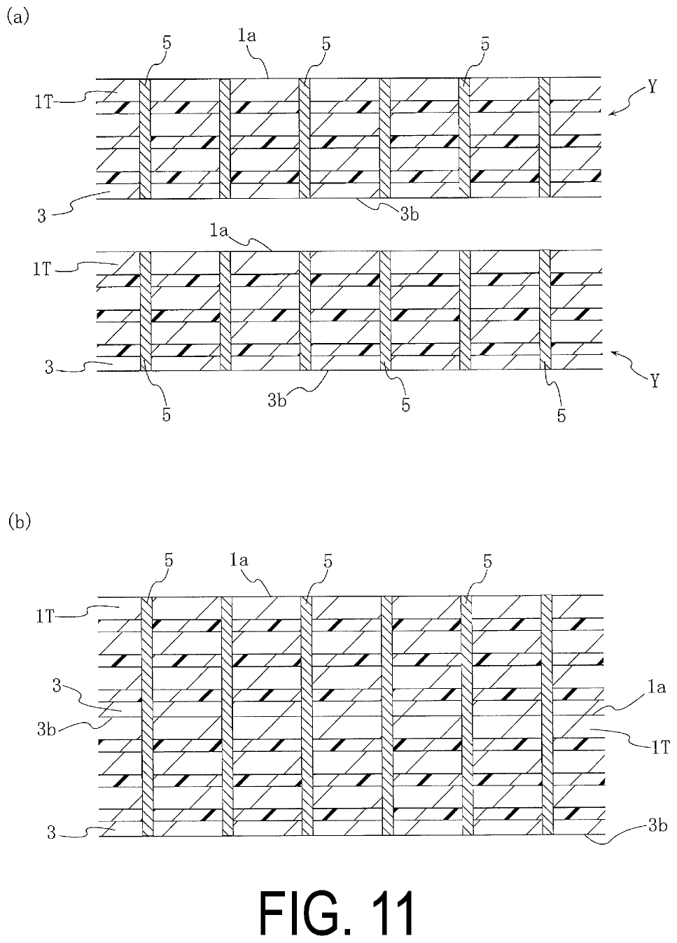

In the multilayering step, as illustrated in FIG. 11, the element forming surface 1a side of the thinned wafer 1T (first wafer) in one wafer laminate Y to be bonded may be bonded to the back surface 3b side of the wafer 3 (second wafer) of another wafer laminate Y (face-to-back bonding between wafer laminates). Examples of the bonding technique include bump bonding and direct bonding described above. FIG. 11 illustrates, as an example, a case of face-to-back bonding of the wafer laminates Y to each other by direct bonding.

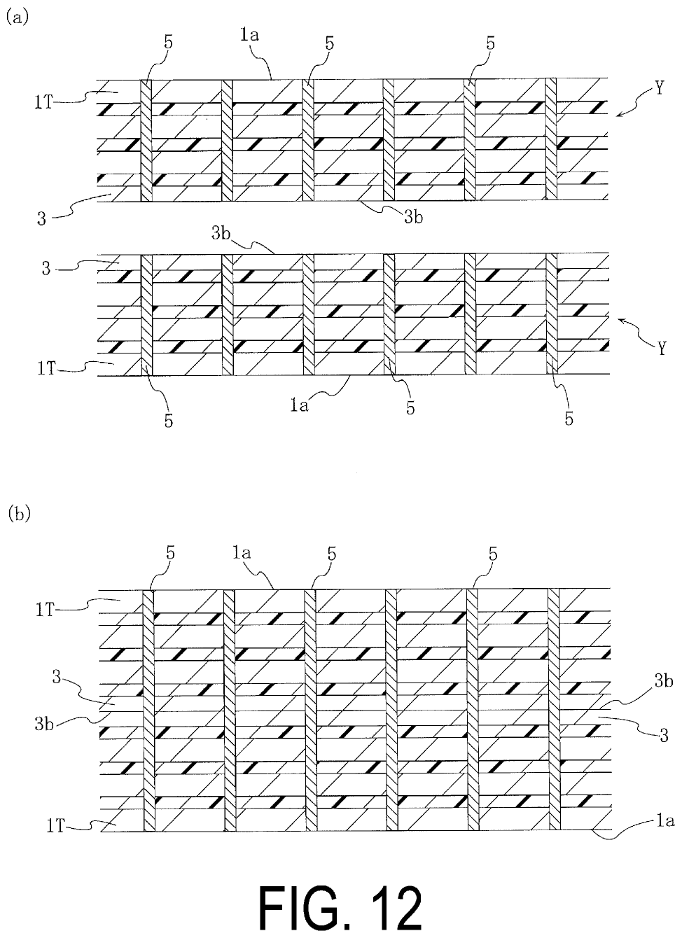

In the multilayering step, as illustrated in FIG. 12, the back surface 3b side of the wafer 3 (second wafer) of one wafer laminate to be bonded may be bonded to the back surface 3b side of the wafer 3 (second wafer) of another wafer laminate Y (back-to-back bonding between wafer laminates). Examples of the bonding technique include bump bonding and direct bonding described above. FIG. 12 illustrates, as an example, a case of back-to-back bonding of the wafer laminates Y to each other by direct bonding.

Subsequently, an insulating film (not illustrated) may be formed on the surfaces of the wafers located at both ends in the lamination direction of the obtained wafer laminate, and an external connection bump (not illustrated) that electrically connects to the wiring structure (not illustrated) in the wafer laminate may be formed on one of the insulating films.

As described above, the semiconductor device having a three-dimensional structure in which semiconductor elements are integrated in their thickness direction can be manufactured. This semiconductor device may be divided into individual pieces by dicing.

In the electrode forming step described above with respect to the semiconductor device manufacturing method of the present embodiment, the through electrode 5 is formed in each wafer laminate Y, the through electrode extending across a plurality of wafers included in each wafer laminate Y. Such a configuration is suited for avoiding or reducing the implementation of a series of steps for forming through electrodes for each wafer in the process of forming the wafer laminate Y (that is, forming an opening through one wafer, forming an insulating film on an inner wall surface of the opening, filling the inside of the openings with a conductive material, implementing cleaning treatment of various aspects associated therewith, and the like) and is suitable for efficiently manufacturing a semiconductor device in a WOW process.

In the above-described multilayering step of the present semiconductor device manufacturing method, two wafer laminates Y, Y in which the through electrodes 5 are already formed are bonded together while the through electrodes 5 are electrically connected between the wafer laminates Y, Y thereof, and wafers are further multilayered. Such a configuration is suitable for achieving a large number of wafer lamination in the WOW process.

In the WOW process, as the number of wafer lamination in the wafer laminate increases, it tends to be difficult to appropriately form an opening extending across the plurality of wafers in the laminate thickness direction, and it tends to be difficult to appropriately form a through electrode in the opening. However, with the present semiconductor device manufacturing method, there is no need to form electrodes that collectively penetrate the wafer laminate Y having the number of lamination corresponding to the number of semiconductor element lamination of the semiconductor device to be manufactured. This type of semiconductor device manufacturing method is suitable for avoiding or suppressing the aforementioned difficulties associated with the batch formation of through electrodes.

As described above, the semiconductor device manufacturing method according to the present embodiment is suitable for efficiently manufacturing semiconductor devices while avoiding or suppressing difficulties in the formation of through electrodes associated with an increase in wafer laminates and achieving a large number of wafer lamination.

Moreover, the present semiconductor device manufacturing method is suitable for increasing the density of semiconductor elements in each wafer when the technique described in, for example, JP 2016-004835 A is employed as the through electrode forming technique in the electrode forming step described above. According to the through electrode forming technique described in the above document, partially conductive portions Ea are formed in each wafer W and are connected to form a through electrode E. However, these partially conductive portions Ea are formed with different cross-sectional areas (cross-sectional area in the wafer in-plane direction) between adjacent wafers, resulting in a structure in which the cross-sectional area of the partially conductive portion Ea inevitably increases gradually with each wafer W as the number of wafer lamination increases. With such a structure, as the number of wafer lamination increases, the surface area in which semiconductor elements can be formed in the wafer W becomes smaller, and as a result, it becomes difficult to increase the density of semiconductor elements. However, with the present semiconductor device manufacturing method described above, there is no need to form electrodes that collectively penetrate a wafer laminate having the number of lamination corresponding to the number of semiconductor element lamination of the semiconductor device to be manufactured. Such a present semiconductor device manufacturing method is suitable for increasing the density of semiconductor elements in each wafer while increasing the number of wafer lamination.

In addition, as described above, with the present semiconductor device manufacturing method, the temporary adhesive for forming the temporary adhesive layer 2 in the reinforced wafer 1R preferably contains: a polyvalent vinyl ether compound (A); a compound (B) having two or more hydroxy groups or carboxy groups that are capable of forming an acetal bond by reacting with a vinyl ether group of the polyvalent vinyl ether compound, the compound (B) capable of forming a polymer with the polyvalent vinyl ether compound; and a thermoplastic resin (C). In the form of the temporary adhesive layer formed by solidification of the temporary adhesive between the supporting substrate S and the wafer 1, the temporary adhesive thus configured is suitable for achieving a relatively high softening temperature of, for example, approximately 130 to 250° C. while ensuring high adhesive strength that can withstand the grinding or the like of the wafer 1 in the thinning step described above with reference to FIG. 1(b).

In the present semiconductor device manufacturing method, the adhesive 4 used in the bonding step described above with reference to FIG. 3 preferably contains, as described above, a polymerizable group-containing polyorganosilsesquioxane. Also as described above, the polymerizable group-containing polyorganosilsesquioxane is suitable for achieving a relatively low polymerization temperature or curing temperature of, for example, around 30 to 200° C. and is suitable for achieving high heat resistance after curing. Thus, the wafer-to-wafer adhesive bonding through the adhesive containing the polymerizable group-containing polyorganosilsesquioxane is suitable for achieving high heat resistance in an adhesive layer to be formed between the wafers and is also suitable for reducing the curing temperature for forming the adhesive layer and thus suppressing damage to the elements in the wafers as adherends.

When the above-described preferred configuration is adopted for both the temporary adhesive for forming the temporary adhesive layer 2 and the adhesive 4 for bonding between wafers, a composite and functional configuration like that described below can be realized. The temporary adhesive layer 2 in the reinforced wafer 1R to be subjected to the bonding step described above with reference to FIG. 3 is suitable for achieving a relatively high softening temperature as described above, and the adhesive 4 (adhesive containing a polymerizable group-containing polyorganosilsesquioxane) used in the bonding step is, as also described above, suitable for achieving a relatively low curing temperature and high heat resistance after curing. Such a composite and functional configuration is suitable for implementing both the bonding step and the subsequent removing step described above with reference to FIG. 4. That is, the configuration thereof is suitable for implementing the bonding step at a relatively low temperature condition to achieve a good adhesive bonding of the thinned wafer 1T to the wafer 3, which is the base wafer, while maintaining the temporary adhesion of the supporting substrate S and the thinned wafer 1T in the reinforced wafer. The configuration thereof is also suitable for implementing the subsequent removing step at a relatively high temperature condition to soften the temporary adhesive layer 2 to remove the supporting substrate S from the thinned wafer 1T while maintaining the adhesive bonding between the wafer 3 and the thinned wafer 1T. The configuration of releasing the temporary adhesion by the temporary adhesive layer 2 through softening the temporary adhesive layer 2 in removing the supporting substrate S from the thinned wafer 1T is suitable for avoiding or suppressing a strong stress applied locally to the thinned wafer 1T, and thereby avoiding damage to the wafer. The composite configuration as described above is suitable for further multilayering thin wafers through adhesive bonding while avoiding wafer damage when forming the wafer laminate Y.

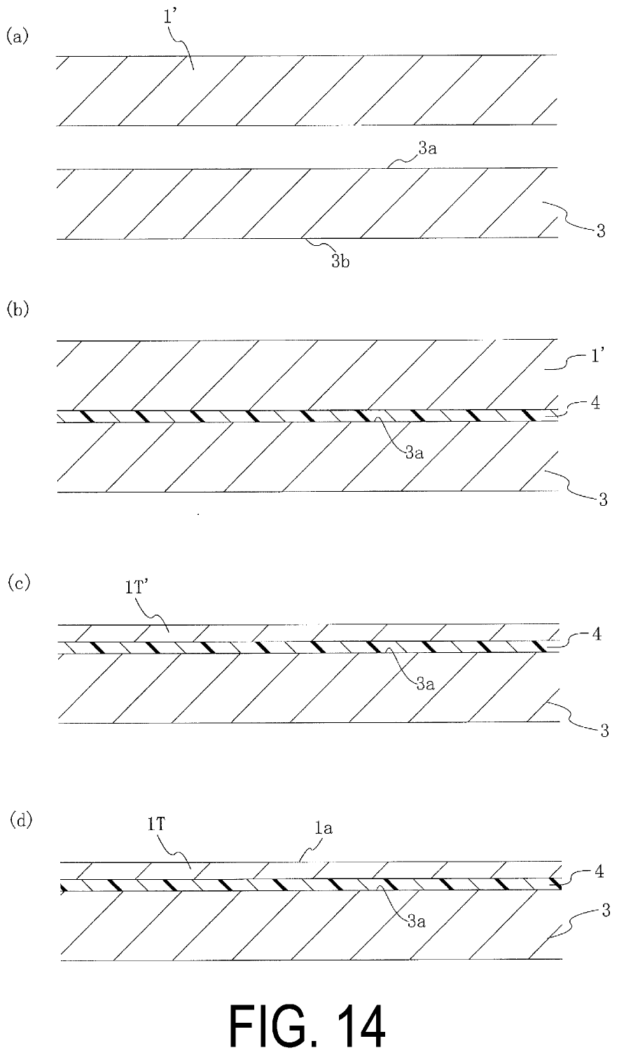

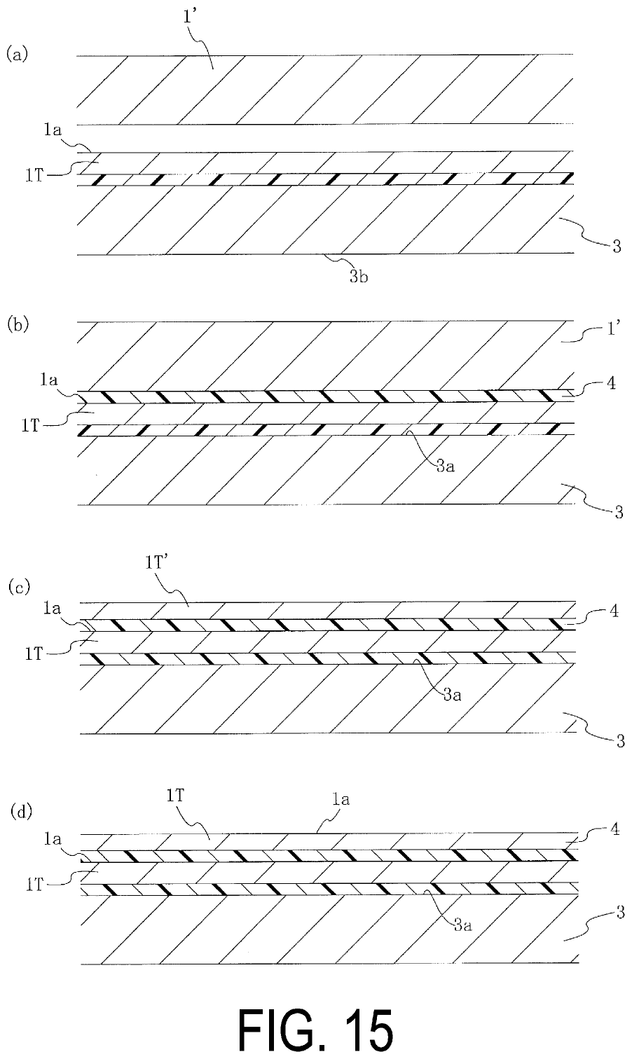

In the present semiconductor device manufacturing method, the wafer laminate Y may be formed through a wafer laminate forming step illustrated in FIGS. 14 and 15 instead of the wafer laminate forming step described above with reference to FIGS. 1 to 6.

In this wafer laminate forming step, first, as illustrated in FIGS. 14(a) and 14(b), a wafer 1′, which is a semiconductor wafer in which semiconductor elements are to be subsequently fabricated, and the wafer 3 having on one side the element forming surface 3a in which a semiconductor element has already been fabricated are bonded through the adhesive 4 described above. Specifically, first, the adhesive 4 is coated by spin coating onto one or both surfaces to be bonded (the element forming surface 3a of the wafer 3, one surface of the wafer 1′) to form an adhesive layer. Prior to the coating of the adhesive 4, one or both surfaces to be bonded may be treated with a silane coupling agent. Then, the adhesive 4 (adhesive layer) is dried and solidified by heating. Then, the surfaces to be bonded are affixed via the adhesive 4 (adhesive layer). Thereafter, the adhesive 4 is cured by heating between the surfaces to be bonded. The thickness of the adhesive layer after curing the adhesive 4 is, for example, from 0.5 to 20 μm. The various conditions for bonding by the adhesive 4 are the same as the various conditions in the bonding step described above with reference to FIG. 3.

Next, as illustrated in FIG. 14(c), the wafer 1′ is thinned. In this step, the wafer 1′ is thinned to a predetermined thickness by, for example, grinding the wafer 1′, and a thinned wafer 1T′ is formed. The thickness of the wafer 1′ (thinned wafer 1T′) after thinning is, for example, from 1 to 20 μm.

Next, as illustrated in FIG. 14(d), the element forming surface 1a is formed on the ground surface side of the thinned wafer 1T′. Specifically, a plurality of semiconductor elements (not illustrated) are fabricated on the ground surface side of the thinned wafer 1T′ through steps such as a transistor formation step and a wiring formation step. As a result, the thinned wafer 1T having the element forming surface 1a is formed on the ground surface side.

Next, as illustrated in FIGS. 15(a) and 15(b), a new wafer 1′, which is a semiconductor wafer in which semiconductor elements are to be subsequently fabricated, is bonded through the above-described adhesive 4 to the thinned wafer 1T. Specifically, first, the adhesive 4 is coated by spin coating onto one or both surfaces to be bonded (the element forming surface 1a of one thinned wafer 1T, one surface of the new wafer 1′) to form an adhesive layer. Prior to the coating of the adhesive 4, one or both surfaces to be bonded may be treated with a silane coupling agent. Then, the adhesive 4 (adhesive layer) is dried and solidified by heating. Then, the surfaces to be bonded are affixed via the adhesive 4 (adhesive layer). Thereafter, the adhesive 4 is cured by heating between the surfaces to be bonded. The thickness of the adhesive layer after curing the adhesive 4 is, for example, from 0.5 to 20 μm. The various conditions for bonding by the adhesive 4 are the same as the various conditions in the bonding step described above with reference to FIG. 3.

Next, as illustrated in FIG. 15(c), the wafer 1′ is thinned. In this step, the wafer 1′ is thinned to a predetermined thickness by, for example, grinding the wafer 1′, and the thinned wafer 1T′ is formed. The thickness of the wafer 1′ (thinned wafer 1T′) after thinning is, for example, from 1 to 20 μm.

Next, as illustrated in FIG. 15(d), the element forming surface 1a is formed on the ground surface side of the thinned wafer 1T′. Specifically, a plurality of semiconductor elements (not illustrated) are fabricated on the ground surface side of the thinned wafer 1T′ through steps such as a transistor formation step and a wiring formation step. As a result, the thinned wafer 1T having the element forming surface 1a is formed on the ground surface side.

In the semiconductor device manufacturing method described above, a wafer laminate forming step may be adopted in which a series of processes are repeated a predetermined number of times as described above, the series of processes including bonding the wafer 1′ to a lower wafer, thinning the wafer 1′, and forming a semiconductor element in the wafer 1′ after thinning.

To summarize the above, configurations and variations of the present invention are described below.

[1] A semiconductor device manufacturing method including:

a wafer laminate forming step of forming at least two wafer laminates each having a laminated structure, the structure including a plurality of wafers, each including an element forming surface and a back surface opposite therefrom, with the element forming surface of one of two adjacent wafers and the back surface of the other of the two adjacent wafers facing each other;

an electrode forming step of forming in each wafer laminate a through electrode extending through the inside of the wafer laminate from an element forming surface side of a first wafer located at one end of the wafer laminate in a lamination direction and having an adjacent wafer positioned at a back surface side thereof, to a position exceeding an element forming surface of a second wafer located at another end;

an electrode end part exposing step of thinning the second wafer of each wafer laminate that has been subjected to the electrode forming step, by grinding a back surface side of the second wafer, and thereby exposing the through electrode at the back surface side; and

a multilayering step in which at least two wafer laminates that have been subjected to the electrode end part exposing step are laminated and bonded while electrically connecting through electrodes between the wafer laminates.

[2] The semiconductor device manufacturing method according to [1], wherein the electrode forming step includes: a step of forming an opening extending from the element forming surface side of the first wafer of the wafer laminate to the position exceeding the element forming surface of the second wafer thereof; and a step of filling an inside of the opening with a conductive material.

[3] The semiconductor device manufacturing method according to [1] or [2], wherein a thickness of the second wafer after thinning in the electrode end part exposing step is from 5 to 200 μm.

[4] The semiconductor device manufacturing method according to any one of [1] to [3], wherein in the multilayering step, an element forming surface side of a first wafer of one wafer laminate to be bonded is bonded to an element forming surface side of a first wafer of another wafer laminate.

[5] The semiconductor device manufacturing method according to any one of [1] to [3], wherein in the multilayering step, an element forming surface side of a first wafer of one wafer laminate to be bonded is bonded to a back surface side of a second wafer of another wafer laminate.

[6] The semiconductor device manufacturing method according to any one of [1] to [3], wherein in the multilayering step, a back surface side of a second wafer of one wafer laminate to be bonded is bonded to a back surface side of a second wafer of another wafer laminate.

[7] The semiconductor device manufacturing method according to any one of [1] to [6], wherein the wafer laminate forming step further includes: a step of bonding a wafer to an element forming surface side of a base wafer including the element forming surface and a back surface opposite therefrom; a step of forming a thinned wafer on the base wafer by grinding the wafer; and a step of forming a semiconductor element on a ground surface side of the thinned wafer.

[8] The semiconductor device manufacturing method according to [7], wherein the wafer laminate forming step further includes: a step of bonding a wafer to an element forming surface side of the thinned wafer on the base wafer; a step of forming a thinned wafer on the base wafer by grinding the wafer; and a step of forming a semiconductor element on a ground surface side of the thinned wafer.

[9] The semiconductor device manufacturing method according to [7] or [8], wherein a thickness of the thinned wafer is from 1 to 20 μm.

[10] The semiconductor device manufacturing method according to any one of [1] to [6], wherein the wafer laminate forming step includes:

a step of preparing a reinforced wafer having a laminated structure that includes a wafer including an element forming surface and a back surface opposite therefrom, a supporting substrate, and a temporary adhesive layer between the element forming surface side of the wafer and the supporting substrate;

a step of forming a thinned wafer by grinding the wafer in the reinforced wafer from the back surface side of the wafer;

a bonding step of bonding, through an adhesive, an element forming surface side of a base wafer to the back surface side of the thinned wafer of the reinforced wafer, the base wafer including the element forming surface and a back surface opposite therefrom; and

a removing step of removing the supporting substrate by releasing temporary adhesion by the temporary adhesive layer between the supporting substrate and the thinned wafer in the reinforced wafer.

[11] The semiconductor device manufacturing method according to [10], wherein the wafer laminate forming step further includes:

a step of preparing at least one additional reinforced wafer having a laminated structure that includes a wafer including an element forming surface and a back surface opposite therefrom, a supporting substrate, and a temporary adhesive layer between the element forming surface side of the wafer and the supporting substrate;

a step of forming a thinned wafer by grinding the wafer of each additional reinforced wafer from the back surface side of the wafer;

at least one additional bonding step in which the back surface side of the thinned wafer in the additional reinforced wafer is bonded through the adhesive to the element forming surface side of the thinned wafer on the base wafer; and

at least one removing step implemented for each of the additional bonding steps to remove the supporting substrate by releasing the temporary adhesion by the temporary adhesive layer between the thinned wafer and the supporting substrate of the additional reinforced wafer.

[12] The semiconductor device manufacturing method according to any one of [1] to [11], wherein a constituent material of the wafer is silicon (Si), germanium (Ge), silicon carbide (SiC), gallium arsenide (GaAs), gallium nitride (GaN), or indium phosphide (InP).

[13] The semiconductor device manufacturing method according to any one of [1] to [12], wherein a thickness of the wafer is not greater than 1000 μm.

[14] The semiconductor device manufacturing method according to any one of [10] to [13], wherein the supporting substrate is a silicon wafer or a glass wafer.

[15] The semiconductor device manufacturing method according to [14], wherein the supporting substrate is a silicon wafer.

[16] The semiconductor device manufacturing method according to any one of [10] to [15], wherein a thickness of the supporting substrate is from 300 μm to 800 μm.

[17] The semiconductor device manufacturing method according to any one of [10] to [16], wherein the thickness of the supporting substrate is from 700 μm to 800 μm.

[18] The semiconductor device manufacturing method according to any one of [10] to [17], wherein temporary adhesive for forming the temporary adhesive layer contains: a polyvalent vinyl ether compound; a compound having two or more hydroxy groups or carboxy groups that are capable of forming an acetal bond by reacting with a vinyl ether group of the polyvalent vinyl ether compound, the compound capable of forming a polymer with the polyvalent vinyl ether compound; and a thermoplastic resin.

[19] The semiconductor device manufacturing method according to any one of [10] to [18], wherein the adhesive layer contains a polymerizable group-containing polyorganosilsesquioxane.

[20] The semiconductor device manufacturing method according to any one of [10] to [19], wherein the polyvalent vinyl ether compound is a compound having two or more vinyl ether groups in a molecule represented by Formula (a) above.

[21] The semiconductor device manufacturing method according to any one of [10] to [19], wherein the polyvalent vinyl ether compound is at least one compound selected from the group consisting of 1,4-butanediol divinyl ether, diethylene glycol divinyl ether, triethylene glycol divinyl ether, and compounds represented by Formulas (a-1) to (a-21) above.

[22] The semiconductor device manufacturing method according to any one of [10] to [19], wherein the polyvalent vinyl ether compound is at least one compound selected from the group consisting of 1,4-butanediol divinyl ether, diethylene glycol divinyl ether, and triethylene glycol divinyl ether.

[23] The semiconductor device manufacturing method according to any one of [10] to [19], wherein the polyvalent vinyl ether compound is at least one compound selected from the group consisting of 1,4-butanediol divinyl ether and triethylene glycol divinyl ether.

[24] The semiconductor device manufacturing method according to any one of [10] to [19], wherein the polyvalent vinyl ether compound is at least one compound selected from the group consisting of diethylene glycol divinyl ether and triethylene glycol divinyl ether.

[25] The semiconductor device manufacturing method according to any one of [10] to [19], wherein the polyvalent vinyl ether compound is at least one compound selected from the group consisting of 1,4-butanediol divinyl ether and diethylene glycol divinyl ether.

[26] The semiconductor device manufacturing method according to any one of [10] to [25], wherein the compound capable of forming a polymer with the polyvalent vinyl ether compound is a compound having two or more constituent units (repeating units) represented by Formula (b) above.

[27] The semiconductor device manufacturing method according to [26], wherein n₂ in Formula (b) above is an integer of from 1 to 3.

[28] The semiconductor device manufacturing method according to [26] or [27], wherein the number of the constituent units (repeating units) represented by

Formula (b) above in the compound capable of forming a polymer with the polyvalent vinyl ether compound is an integer of from 2 to 40.

[29] The semiconductor device manufacturing method according to any one of [26] to [28], wherein a proportion of the constituent units (repeating units) represented by Formula (b) above in the compound capable of forming a polymer with the polyvalent vinyl ether compound is not less than 30 mass %, and the X is a hydroxy group.

[30] The semiconductor device manufacturing method according to any one of [26] to [28], wherein a proportion of the constituent units (repeating units) represented by Formula (b) above in the compound capable of forming a polymer with the polyvalent vinyl ether compound is not less than 1 mass %, and the X is a carboxy group.

[31] The semiconductor device manufacturing method according to any one of [26] to [30], wherein the constituent units (repeating units) represented by Formula (b) above are at least one type of constituent unit selected from the group consisting of Formulas (b-1) to (b-6) above.

[32] The semiconductor device manufacturing method according to any one of [26] to [30], wherein the constituent units (repeating units) represented by Formula (b) above are at least one type of constituent unit selected from the group consisting of Formulas (b-1), (b-2), (b-3), (b-4), and (b-5) above.

[33] The semiconductor device manufacturing method according to any one of [26] to [30], wherein the constituent units (repeating units) represented by Formula (b) above are at least one type of constituent unit selected from the group consisting of Formulas (b-1), (b-2), (b-3), (b-4), and (b-6) above.

[34] The semiconductor device manufacturing method according to any one of [26] to [30], wherein the constituent units (repeating units) represented by Formula (b) above are at least one type of constituent unit selected from the group consisting of Formulas (b-1), (b-2), (b-3), (b-5), and (b-6) above.

[35] The semiconductor device manufacturing method according to any one of [26] to [30], wherein the constituent units (repeating units) represented by Formula (b) above are at least one type of constituent unit selected from the group consisting of Formulas (b-1), (b-2), (b-4), (b-5), and (b-6) above.

[36] The semiconductor device manufacturing method according to any one of [26] to [30], wherein the constituent units (repeating units) represented by Formula (b) above are at least one type of constituent unit selected from the group consisting of Formulas (b-1), (b-3), (b-4), (b-5), and (b-6) above.

[37] The semiconductor device manufacturing method according to any one of [26] to [30], wherein the constituent units (repeating units) represented by Formula (b) above are at least one type of constituent unit selected from the group consisting of Formulas (b-1), (b-2), (b-3), and (b-4) above.

[38] The semiconductor device manufacturing method according to any one of [26] to [30], wherein the constituent units (repeating units) represented by Formula (b) above are at least one type of constituent unit selected from the group consisting of Formulas (b-1), (b-2), (b-3), and (b-5) above.

[39] The semiconductor device manufacturing method according to any one of [26] to [30], wherein the constituent units (repeating units) represented by Formula (b) above are at least one type of constituent unit selected from the group consisting of Formulas (b-1), (b-2), (b-4), and (b-5) above.

[40] The semiconductor device manufacturing method according to any one of [26] to [30], wherein the constituent units (repeating units) represented by Formula (b) above are at least one type of constituent unit selected from the group consisting of Formulas (b-1), (b-3), (b-4), and (b-5) above.

[41] The semiconductor device manufacturing method according to any one of [26] to [30], wherein the constituent units (repeating units) represented by Formula (b) above are at least one type of constituent unit selected from the group consisting of Formulas (b-1), (b-2), (b-3), and (b-6) above.

[42] The semiconductor device manufacturing method according to any one of [26] to [30], wherein the constituent units (repeating units) represented by Formula (b) above are at least one type of constituent unit selected from the group consisting of Formulas (b-1), (b-2), (b-4), and (b-6) above.

[43] The semiconductor device manufacturing method according to any one of [26] to [30], wherein the constituent units (repeating units) represented by Formula (b) above are at least one type of constituent unit selected from the group consisting of Formulas (b-1), (b-3), (b-4), and (b-6) above.

[44] The semiconductor device manufacturing method according to any one of [26] to [30], wherein the constituent units (repeating units) represented by Formula (b) above are at least one type of constituent unit selected from the group consisting of Formulas (b-1), (b-2), (b-5), and (b-6) above.

[45] The semiconductor device manufacturing method according to any one of [26] to [30], wherein the constituent units (repeating units) represented by Formula (b) above are at least one type of constituent unit selected from the group consisting of Formulas (b-1), (b-3), (b-5), and (b-6) above.

[46] The semiconductor device manufacturing method according to any one of [26] to [30], wherein the constituent units (repeating units) represented by Formula (b) above are at least one type of constituent unit selected from the group consisting of Formulas (b-1), (b-4), (b-5), and (b-6) above.

[47] The semiconductor device manufacturing method according to any one of [26] to [30], wherein the constituent units (repeating units) represented by Formula (b) above are at least one type of constituent unit selected from the group consisting of Formulas (b-1), (b-2), and (b-3) above.

[48] The semiconductor device manufacturing method according to any one of [26] to [30], wherein the constituent units (repeating units) represented by Formula (b) above are at least one type of constituent unit selected from the group consisting of Formulas (b-1), (b-2), and (b-4) above.

[49] The semiconductor device manufacturing method according to any one of [26] to [30], wherein the constituent units (repeating units) represented by Formula (b) above are at least one type of constituent unit selected from the group consisting of Formulas (b-1), (b-3), and (b-4) above.

[50] The semiconductor device manufacturing method according to any one of [26] to [30], wherein the constituent units (repeating units) represented by Formula (b) above are at least one type of constituent unit selected from the group consisting of Formulas (b-1), (b-2), and (b-6) above.

[51] The semiconductor device manufacturing method according to any one of [26] to [30], wherein the constituent units (repeating units) represented by Formula (b) above are at least one type of constituent unit selected from the group consisting of Formulas (b-1), (b-3), and (b-6) above.

[52] The semiconductor device manufacturing method according to any one of [26] to [30], wherein the constituent units (repeating units) represented by Formula (b) above are at least one type of constituent unit selected from the group consisting of Formulas (b-1), (b-5), and (b-6) above.

[53] The semiconductor device manufacturing method according to any one of [26] to [30], wherein the constituent units (repeating units) represented by Formula (b) above are at least one type of constituent unit selected from the group consisting of Formulas (b-1) and (b-2) above.

[54] The semiconductor device manufacturing method according to any one of [26] to [30], wherein the constituent units (repeating units) represented by Formula (b) above are at least one type of constituent unit selected from the group consisting of Formulas (b-1) and (b-3) above.

[55] The semiconductor device manufacturing method according to any one of [26] to [30], wherein the constituent units (repeating units) represented by Formula (b) above are at least one type of constituent unit selected from the group consisting of Formulas (b-1) and (b-4) above.

[56] The semiconductor device manufacturing method according to any one of [26] to [30], wherein the constituent units (repeating units) represented by Formula (b) above are at least one type of constituent unit selected from the group consisting of Formulas (b-1) and (b-5) above.

[57] The semiconductor device manufacturing method according to any one of [26] to [30], wherein the constituent units (repeating units) represented by Formula (b) above are at least one type of constituent unit selected from the group consisting of Formulas (b-1) and (b-6) above.

[58] The semiconductor device manufacturing method according to any one of [26] to [57], wherein the compound capable of forming a polymer with the polyvalent vinyl ether compound is a homopolymer having only the constituent units (repeating units) represented by Formula (b) above.

[59] The semiconductor device manufacturing method according to any one of [26] to [57], wherein the compound capable of forming a polymer with the polyvalent vinyl ether compound is a block polymer, a graft polymer, or a random polymer having a constituent unit (repeating unit) represented by Formula (b) above and another constituent unit.

[60] The semiconductor device manufacturing method according to [59], wherein the other constituent unit is a constituent unit derived from at least one polymerizable monomer selected from the group consisting of chain olefins, aromatic vinyl compounds, unsaturated carboxylic acid esters, carboxylic acid vinyl esters, and unsaturated dicarboxylic acid diesters.

[61] The semiconductor device manufacturing method according to [60], wherein the aromatic vinyl compound is a constituent unit derived from at least one polymerizable monomer selected from the group consisting of styrene, vinyl toluene, and α-methylstyrene.

[62] The semiconductor device manufacturing method according to [60], wherein the aromatic vinyl compound is a constituent unit derived from at least one polymerizable monomer selected from the group consisting of styrene and vinyl toluene.

[63] The semiconductor device manufacturing method according to [60], wherein the aromatic vinyl compound is a constituent unit derived from at least one polymerizable monomer selected from the group consisting of styrene and α-methylstyrene.

[64] The semiconductor device manufacturing method according to any one of [10] to [63], wherein the softening point of the compound capable of forming a polymer with the polyvalent vinyl ether compound is from 50° C. to 250° C.

[65] The semiconductor device manufacturing method according to any one of [10] to [64], wherein a weight average molecular weight (by the GPC method calibrated with polystyrene standards) of the compound capable of forming a polymer with the polyvalent vinyl ether compound is not lower than 1500.

[66] The semiconductor device manufacturing method according to any one of [10] to [65], wherein the thermoplastic resin is at least one selected from the group consisting of polyvinyl acetal resins, polyester resins, polyurethane resins, and polyamide resins.

[67] The semiconductor device manufacturing method according to any one of [10] to [65], wherein the thermoplastic resin is at least one selected from the group consisting of polyvinyl acetal resins and polyester resins.

[68] The semiconductor device manufacturing method according to [66] or [67], wherein the polyvinyl acetal resin is at least one selected from the group consisting of polyvinyl formal and polyvinyl butyral.

[69] The semiconductor device manufacturing method according to [66] or [67], wherein the polyester resin is a polyester obtained by ring-opening polymerization of lactone.

[70] The semiconductor device manufacturing method according to [66] or [67], wherein the polyester resin is a polyester obtained by ring-opening polymerization of at least one selected from the group consisting of ϵ-caprolactone, δ-valerolactone, and γ-butyrolactone.

[71] The semiconductor device manufacturing method according to [66] or [67], wherein the polyester resin is a polyester obtained by ring-opening polymerization of at least one selected from the group consisting of ϵ-caprolactone and γ-butyrolactone.

[68] The semiconductor device manufacturing method according to [66] or [67], wherein the polyester resin is a polyester obtained by ring-opening polymerization of at least one selected from the group consisting of ϵ-caprolactone and δ-valerolactone.

[69] The semiconductor device manufacturing method according to any one of [18] to [68], wherein a weight average molecular weight Mw (by the GPC method calibrated with polystyrene standards) of the thermoplastic resin is from 1500 to 100000.

[70] The semiconductor device manufacturing method according to any one of [18] to [69], wherein a content of the thermoplastic resin in the temporary adhesive is from 0.1 to 3 parts by mass per 1 part by mass of the compound capable of forming a polymer with the polyvalent vinyl ether compound.

[71] The semiconductor device manufacturing method according to any one of [10] to [70], wherein the temporary adhesive further contains a monohydric alcohol and/or a monovalent carboxylic acid.

[72] The semiconductor device manufacturing method according to any one of [10] to [71], wherein a softening point of the temporary adhesive is from 130 to 250° C.

[73] The semiconductor device manufacturing method according to any one of [10] to [72], wherein a thickness of the thinned wafer is from 1 to 20 μm.

[74] The semiconductor device manufacturing method according to any one of [19] to [73], wherein the polymerizable group-containing polyorganosilsesquioxane contains constituent units represented by Formula (1) above and Formula (2) above.

[75] The semiconductor device manufacturing method according to [74], wherein R¹ in Formula (1) above and Formula (2) above is a group containing an epoxy group or a (meth)acryloyl group.

[76] The semiconductor device manufacturing method according to [75], wherein the group containing an epoxy group is at least one of the groups represented by Formulas (3) to (6) above.

[77] The semiconductor device manufacturing method according to [75], wherein the group containing an epoxy group is at least one of the groups represented by Formulas (3), (4), and (5) above.

[78] The semiconductor device manufacturing method according to [75], wherein the group containing an epoxy group is at least one of the groups represented by Formulas (3), (5), and (6) above.

[79] The semiconductor device manufacturing method according to [75], wherein the group containing an epoxy group is at least one of the groups represented by Formulas (3), (4), and (6) above.

[80] The semiconductor device manufacturing method according to [75], wherein the group containing an epoxy group is at least one of the groups represented by Formulas (3) and (4) above.

[81] The semiconductor device manufacturing method according to [75], wherein the group containing an epoxy group is at least one of the groups represented by Formulas (3) and (5) above.

[82] The semiconductor device manufacturing method according to [75], wherein the group containing an epoxy group is at least one of the groups represented by Formulas (3) and (6) above.

[83] The semiconductor device manufacturing method according to [75], wherein the group containing an epoxy group is a 2-(3,4-epoxycyclohexyl)ethyl group.

[84] The semiconductor device manufacturing method according to any one of [19] to [83], wherein a number average molecular weight Mn (by the GPC method calibrated with polystyrene standards) of the polymerizable group-containing polyorganosilsesquioxane is from 1000 to 50000.

[85] The semiconductor device manufacturing method according to any one of [19] to [84], wherein a molecular weight dispersity (Mw/Mn) of the polymerizable group-containing polyorganosilsesquioxane is from 1.0 to 4.0.

[86] The semiconductor device manufacturing method according to any one of [10] to [85], wherein a thickness of the base wafer in the bonding step is from 300 μm to 1000 μm.

[87] The semiconductor device manufacturing method according to any one of [10] to [86], wherein the bonding step includes curing treatment to cure the adhesive at a temperature lower than a softening point of the polymer, and the removing step includes softening treatment to soften the temporary adhesive layer at a temperature higher than the softening point of the polymer.

[88] The semiconductor device manufacturing method according to [87], wherein a temperature of the curing treatment is from 30 to 200° C.

[89] The semiconductor device manufacturing method according to [87] or [88], wherein a thickness of the adhesive layer after the curing is from 0.5 to 20 μm.

[90] The semiconductor device manufacturing method according to any one of [87] to [89], wherein a temperature of the softening treatment is from 170° C. to 250° C.

### INDUSTRIAL APPLICABILITY

The manufacturing method of the present invention is suitable for efficiently manufacturing a semiconductor device while avoiding or suppressing difficulties in the formation of through electrodes associated with an increase in wafer laminates and achieving a large number of wafer lamination.

Moreover, the manufacturing method of the present invention is suitable for achieving good adhesive bonding of a thinned wafer to a base wafer while maintaining temporary adhesion of a supporting substrate and the thinned wafer in a reinforced wafer and is suitable for softening the temporary adhesive layer and removing the supporting substrate from the thinned wafer while maintaining the adhesive bonding between the base wafer and the thinned wafer in a subsequent removing step. Thus, when manufacturing a semiconductor device in which semiconductor elements are multilayered through the lamination of wafers in which the semiconductor elements are fabricated, the manufacturing method of the present invention can multilayer thin wafers through an adhesive while avoiding wafer damage.

Thus, the present invention is industrially applicable.

### REFERENCE SIGNS LIST

S Supporting substrate
1, 1′ Wafer
1T, 1T′ Thinned wafer
1a, 3a Element forming surface
1b, 3b Back surface
1R Reinforced wafer
3 Wafer (base wafer)
2 Temporary adhesive layer
4 Adhesive
5 Through electrode
Y Wafer laminate

1. A semiconductor device manufacturing method comprising:
a wafer laminate forming step of forming at least two wafer laminates each having a laminated structure, the structure including a plurality of waters, each including an element forming surface and a back surface opposite therefrom, with the element forming surface of one of two adjacent wafers and the back surface of the other of the two adjacent wafers facing each other;
an electrode forming step of forming in each wafer laminate a through electrode extending through an inside of the wafer laminate, from a side of an element forming surface of a first wafer located at one end of the wafer laminate in a lamination direction and having an adjacent water positioned at a side of a back surface thereof, to a position exceeding an element forming surface of a second wafer located at another end;
an electrode end part exposing step of thinning the second wafer of each wafer laminate that has been subjected to the electrode forming step, by grinding a side of a back surface of the second wafer, and thereby exposing the through electrode at the side of the back surface; and
a multilayering step in which at least two wafer laminates that have been subjected to the electrode end part exposing step are laminated and bonded while electrically connecting the through electrodes between the wafer laminates.

2. The semiconductor device manufacturing method according to claim 1, wherein the electrode forming step comprises: a step of forming an opening extending from the side of the element forming surface of the first wafer of the wafer laminate to the position exceeding the element forming surface of the second wafer thereof, and a step of filling an inside of the opening with a conductive material.

3. The semiconductor device manufacturing method according to claim 1, wherein in the multilayering step, a side of an element forming surface of a first wafer of one wafer laminate to be bonded is bonded to a side of an element forming surface of a first wafer of another wafer laminate.

4. The semiconductor device manufacturing method according to claim 1, wherein in the multilayering step, a side of an element forming surface of a first wafer of one wafer laminate to be bonded is bonded to a side of a back surface of a second wafer of another wafer laminate,

5. The semiconductor device manufacturing method according to claim 1, wherein in the multilayering step, a side of a back surface of a second wafer of one wafer laminate to be bonded is bonded to a side of a back surface of a second wafer of another wafer laminate.

6. The semiconductor device manufacturing method according to claim 1, wherein the wafer laminate forming step further comprises: a step of bonding a wafer to a side of an element forming surface of a base wafer including the element forming surface and a back surface opposite therefrom; a step of forming a thinned wafer on the base wafer by grinding the wafer; and a step of forming a semiconductor element on a side of a around surface of the thinned wafer.

7. The semiconductor device manufacturing method according to claim 6, wherein the wafer laminate forming step further comprises: a step of bonding a wafer to a side of an element forming surface of the thinned wafer on the base wafer; a step of forming a thinned wafer on the base wafer by grinding the wafer; and a step of forming a semiconductor element on a side of a ground surface of the thinned wafer.

8. The semiconductor device manufacturing method according to claim 1, wherein the wafer laminate forming step comprises:
a step of preparing a reinforced water having a laminated structure that includes: a wafer including an element forming surface and a back surface opposite therefrom, a supporting substrate, and a temporary adhesive layer between a side of the element forming surface of the wafer and the supporting substrate;
a step of forming a thinned wafer by grinding the wafer in the reinforced wafer from a side of the back surface of the wafer;
a bonding step of bonding, through an adhesive, a side of an element forming surface of a base wafer to the side of the back surface of the thinned wafer of the reinforced wafer, the base wafer including the element forming surface and a back surface opposite therefrom; and
a removing step of removing the supporting substrate by releasing temporary adhesion by the temporary adhesive layer between the supporting substrate and the thinned wafer in the reinforced wafer.

9. The semiconductor device manufacturing method according to claim 8, wherein the wafer laminate forming step further comprises:
a step of preparing at least one additional reinforced wafer having a. laminated structure that includes: a wafer including an element forming surface and a back surface opposite therefrom, a supporting substrate, and a temporary adhesive layer between a side of the element forming surface of the wafer and the supporting substrate;
a step of forming a thinned wafer by grinding the wafer of each additional reinforced wafer from a side of the back surface of the wafer;
at least one additional bonding step in which the side of the back surface of the thinned wafer in the additional reinforced water is bonded through the adhesive to the side of the element forming surface of the thinned wafer on the base wafer; and
at least one removing step implemented for each of the additional bonding steps to remove the supporting substrate by releasing the temporary adhesion by the temporary adhesive layer between the thinned wafer and the supporting substrate of the additional reinforced water.

10. The semiconductor device manufacturing method according to claim 8, wherein temporary adhesive for forming the temporary adhesive layer comprises: a polyvalent vinyl ether compound; a compound having two or more hydroxy groups or carboxy groups that are capable of forming an acetal bond by reacting with a vinyl ether group of the polyvalent vinyl ether compound, the compound capable of forming a polymer with the polyvalent vinyl ether compound; and a thermoplastic resin.

11. The semiconductor device manufacturing method according to claim 8, wherein the adhesive contains a polymerizable group-containing polyorganosilsesquioxane.

12. The semiconductor device manufacturing method according to claim 8, wherein the bonding step comprises curing treatment to cure the adhesive at a temperature lower than a softening point of the polymer, and
the removing step comprises softening treatment to soften the temporary adhesive layer at a temperature higher than the softening point of the polymer.

13. The semiconductor device manufacturing method according to claim 10, wherein the polyvalent vinyl ether compound is a compound having two or more vinyl ether groups in a molecule represented by Formula (a) below: 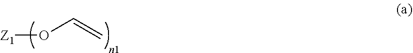
where Z₁ represents a group in which n₁ hydrogen atoms are removed from a structural formula of a saturated or unsaturated aliphatic hydrocarbon, a saturated or unsaturated alicyclic hydrocarbon, an aromatic hydrocarbon, a heterocyclic compound, or a bonded body in which any of these are bonded via a single bond or a linking group; and n₁ represents an integer of 2 or greater.

14. The semiconductor device manufacturing method according to claim 10, wherein the polyvalent vinyl ether compound is at least one compound selected from the group consisting of 1,4-butanediol divinyl ether, diethylene glycol divinyl ether and triethylene glycol divinyl ether.

15. The semiconductor device manufacturing method according to claim 10, wherein the compound capable of forming a polymer with the polyvalent vinyl ether compound is a compound having two or more constituent units (repeating units) represented by Formula (b) below: 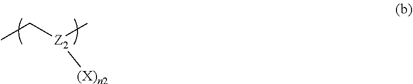
where X represents a hydroxy group or a carboxy group; and n₂ represents an integer of 1 or greater; and n₂ X's may be identical or different from each other; and Z₂ represents a group in which (n₂+2) hydrogen atoms are removed from a structural formula of a saturated or unsaturated aliphatic hydrocarbon, a saturated or unsaturated alicyclic hydrocarbon, an aromatic hydrocarbon, a heterocyclic compound, or a bonded body in which any of these are bonded via a single bond or a linking group.

16. The semiconductor device manufacturing method according to claim 15, wherein the constituent units (repeating units) represented by Formula (b) above are at least one type of constituent unit selected from the group consisting of Formulas (b-1) to (b-6) below.

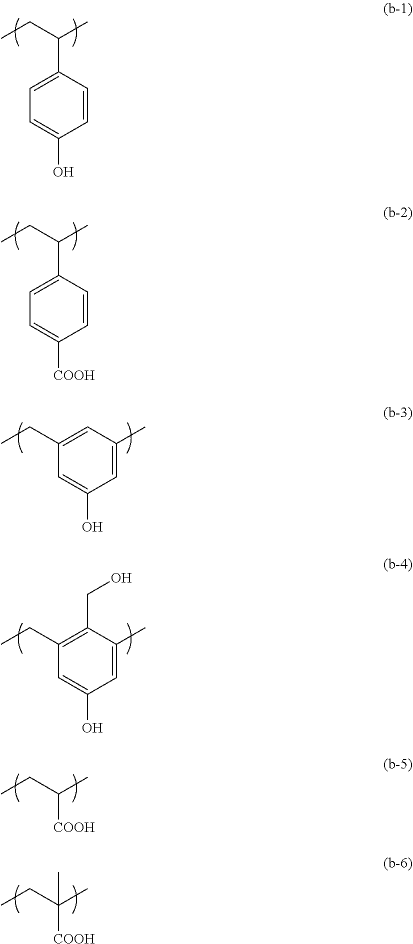

17. The semiconductor device manufacturing method according to claim 10, wherein the thermoplastic resin is at least one selected from the group consisting of polyvinyl acetal resins, polyester resins, polyurethane resins, and polyamide resins.

18. The semiconductor device manufacturing method according to claim 11, wherein the polymerizable group-containing polyorganosilsesquioxane contains constituent units represented by Formula (1) and Formula (2) below:
[R¹SiO_{3/2}] (1)
[R¹SiO_{2/2}(OR²)] (2)
where R¹ represents a group containing an epoxy group or a (meth)acryloyloxy group; and R² represents a hydrogen atom or an alkyl group having from 1 to 4 carbon atoms.

19. The semiconductor device manufacturing method according to claim 18, wherein the group containing an epoxy group is at least one of groups represented by Formulas (3) to (6) below: 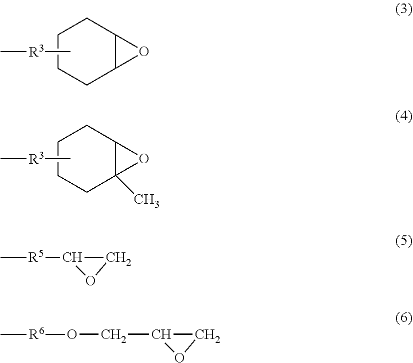
where each of R³, R⁴, R⁵, and R⁶ represents a linear or branched alkylene group having from 1 to 10 carbon atoms.

20. The semiconductor device manufacturing method according to claim 18, wherein the polymerizable group-containing polyorganosilsesquioxane contains constituent units represented by Formula (7) and Formula (8) below:
[R⁷SiO_{3/2}] (7)
[R⁷SiO_{2/2}(OR²)] (8)
where R⁷ represents a hydrogen atom, a substituted or unsubstituted alkyl group, a substituted or unsubstituted alkenyl group, a substituted or unsubstituted cycloalkyl group, a substituted or unsubstituted aryl group, or a substituted or unsubstituted aralkyl group; and R² represents a hydrogen atom or an alkyl group having from 1 to 4 carbon atoms.
